(19) United States
(12) Patent Application Publication
(10) Pub. No.: US 2024/0422975 A1
(43) Pub. Date: Dec. 19, 2024

(54) THREE-DIMENSIONAL SEMICONDUCTOR MEMORY DEVICE AND ELECTRONIC SYSTEM INCLUDING THE SAME

(71) Applicant: Samsung Electronics Co., Ltd., Suwon-si (KR)

(72) Inventors: Kwangyoung Jung, Suwon-si (KR); Sunil Shim, Suwon-si (KR); Seung-Jun Lee, Suwon-si (KR); Joohyun Lim, Suwon-si (KR); Yoojin Jeon, Suwon-si (KR)

(21) Appl. No.: 18/590,354

(22) Filed: Feb. 28, 2024

(30) Foreign Application Priority Data
Jun. 19, 2023 (KR) 10-2023-0078241

(51) Int. Cl. H10B 43/27; H10B 43/40

(52) U.S. Cl. CPC H10B 43/27; H10B 43/40

(57) ABSTRACT

A three-dimensional semiconductor memory device may include a peripheral circuit structure on a peripheral substrate, a cell array structure on the peripheral circuit structure, the cell array structure including a cell array region and an outer region, a source structure on the cell array region, a base pattern on the outer region, a cell vertical structure that extends into the cell array structure in the cell array region and is electrically connected to the source structure, an outer vertical structure that extends into the cell array structure in the outer region, and a filling pattern that extends from the outer vertical structure and into the base pattern. The filling pattern defines a void, a top end of the cell vertical structure extends from the peripheral substrate by a first distance, and a top surface of the source structure extends from the peripheral substrate by a second distance.

### CROSS-REFERENCE TO RELATED APPLICATION

This U.S. non-provisional patent application claims priority under 35 U.S.C. § 119 to Korean Patent Application No. 10-2023-0078241, filed on Jun. 19, 2023, in the Korean Intellectual Property Office, the entire contents of which are hereby incorporated by reference.

### TECHNICAL FIELD

The present disclosure relates to a three-dimensional semiconductor memory device and an electronic system including the same, and in particular, a three-dimensional semiconductor memory device including a peripheral circuit structure and a cell array structure, which are bonded to each other through bonding pads, and an electronic system including the same.

### BACKGROUND

A semiconductor device configured to store a large amount of data is desired as a data storage of an electronic system. Higher integration of semiconductor devices is desirable to satisfy consumer demands for large data storing capacity, superior performance, and inexpensive prices. In the case of two-dimensional or planar semiconductor devices, since their integration is determined by the area occupied by a unit memory cell, integration is greatly influenced by the level of a fine pattern forming technology. However, the extremely expensive process equipment needed to increase pattern fineness sets a practical limitation on increasing integration for two-dimensional or planar semiconductor devices. Thus, three-dimensional semiconductor memory devices including three-dimensionally arranged memory cells have recently been proposed.

### SUMMARY

An embodiment of the present disclosure provides a three-dimensional semiconductor memory device, which is configured to reduce a process difficulty in a process of fabricating the same, and an electronic system including the same.

An embodiment of the present disclosure provides a three-dimensional semiconductor memory device, which is configured to reduce a process failure in a process of fabricating the same, and an electronic system including the same.

According to an embodiment of the present disclosure, a three-dimensional semiconductor memory device may include a peripheral circuit structure on a peripheral substrate; a cell array structure on the peripheral circuit structure, the cell array structure including a cell array region and an outer region; a source structure on the cell array region; a base pattern on the outer region; a cell vertical structure that extends into the cell array structure in the cell array region and is electrically connected to the source structure; an outer vertical structure that extends into the cell array structure in the outer region; and a plurality of filling patterns that extend from the outer vertical structure into the base pattern; where at least one filling pattern from among the plurality respectively define at least one void, where a top end of the cell vertical structure extends from the peripheral substrate by a first distance, where a top surface of the source structure extends from the peripheral substrate by a second distance, and where the first distance is less than the second distance.

According to an embodiment of the present disclosure, a three-dimensional semiconductor memory device may include a peripheral circuit structure on a peripheral substrate; a cell array structure on the peripheral circuit structure, the cell array structure including a cell array region and an outer region; a source structure on the cell array region; a base pattern on the outer region; a cell vertical structure that extends into the cell array structure in the cell array region and is electrically connected to the source structure; an outer vertical structure that extends into the cell array structure in the outer region; and a filling pattern that extends from the outer vertical structure and into the base pattern, where the source structure includes a protruding portion that is on the cell vertical structure and extends into the cell array structure.

According to an embodiment of the present disclosure, an electronic system may include a three-dimensional semiconductor memory device; and a controller that is electrically connected to the three-dimensional semiconductor memory device through an input/output pad, where the controller is configured to control the three-dimensional semiconductor memory device, where the three-dimensional semiconductor memory device includes: a peripheral circuit structure on a peripheral substrate; a cell array structure on the peripheral circuit structure, the cell array structure including a cell array region and an outer region; a source structure on the cell array region; a base pattern on the outer region; a cell vertical structure that extends into the cell array structure in the cell array region and is electrically connected to the source structure; an outer vertical structure that extends into the cell array structure in the outer region; and a filling pattern that extends from the outer vertical structure and into the base pattern, where the filling pattern defines a void, where a top end of the cell vertical structure extends from the peripheral substrate by a first distance, where a top surface of the source structure extends from the peripheral substrate by a second distance, and where the first distance is less than the second distance.

### BRIEF DESCRIPTION OF THE DRAWINGS

FIG. 1 is a diagram schematically illustrating an electronic system including a three-dimensional semiconductor memory device according to an embodiment of the present disclosure.

FIG. 2 is a perspective view schematically illustrating an electronic system including a three-dimensional semiconductor memory device according to an embodiment of the present disclosure.

FIGS. 3 and 4 are sectional views, which are respectively taken along lines I-I′ and II-II′ of FIG. 2 to illustrate a semiconductor package including a three-dimensional semiconductor memory device according to an embodiment of the present disclosure.

FIG. 5 is a plan view illustrating a three-dimensional semiconductor memory device according to an embodiment of the present disclosure.

FIGS. 6A, 6B, 6C, and 6D are sectional views taken along lines A-A′, B-B′, C-C′ and A-A′ of FIG. 5.

FIGS. 7A, 7B, and 7C are enlarged views corresponding to a portion P1 of FIG. 6A.

FIGS. 7D, 7E, and 7F are enlarged views corresponding to a portion P2 of FIG. 6A.

FIGS. 8A, 8B, and 8C are enlarged views corresponding to a portion P3 of FIG. 6B.

FIGS. 9A, 9B, 10A, 10B, 11A, 11B, 12A, 12B, 13A, and 13B are sectional views illustrating a method of fabricating a three-dimensional semiconductor memory device according to an embodiment of the present disclosure.

FIGS. 14, 16, and 18 are enlarged views corresponding to a portion P1 of FIG. 11A.

FIGS. 15, 17, and 19 are enlarged views corresponding to a portion P1 of FIG. 12A.

FIGS. 20, 21, and 22 are enlarged views corresponding to a portion P2 of FIG. 11A.

FIGS. 23, 25, and 27 are enlarged views corresponding to a portion P3 of FIG. 12B.

FIGS. 24, 26, and 28 are enlarged views corresponding to a portion P3 of FIG. 13B.

### DETAILED DESCRIPTION

To clarify the present disclosure, parts that are not connected with the description will be omitted, and the same elements or equivalents are referred to by the same reference numerals throughout the specification. Further, since sizes and thicknesses of constituent members shown in the accompanying drawings are arbitrarily given for better understanding and ease of description, the present disclosure is not limited to the illustrated sizes and thicknesses. In the drawings, the thickness of layers, films, panels, regions, etc., are exaggerated for clarity. In the drawings, for better understanding and ease of description, thicknesses of some layers and areas are excessively displayed.

It will be understood that when an element such as a layer, film, region, or substrate is referred to as being “on” another element, it can be directly on the other element or intervening elements may also be present. In contrast, when an element is referred to as being “directly on” another element, there are no intervening elements present. Further, spatially relative terms, such as “beneath,” “below,” “lower,” “above,” “upper,” and the like, may be used herein for ease of description to describe one element's or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the term “below” can encompass both an orientation of above and below. The device may be otherwise oriented (rotated 90 degrees or at other orientations), and the spatially relative descriptors used herein may be interpreted accordingly.

In addition, unless explicitly described to the contrary, the word “comprises”, and variations such as “comprises” or “comprising”, will be understood to imply the inclusion of stated elements but not the exclusion of any other elements. As used herein, the phrase “at least one of A, B, and C” refers to a logical (A OR B OR C) using a non-exclusive logical OR, and should not be construed to mean “at least one of A, at least one of B and at least one of C.” As used herein, the singular forms “a,” “an” and “the” are intended to include the plural forms as well, unless the context clearly indicates otherwise. It will be further understood that the terms “comprises,” “comprising,” “includes” and/or “including,” when used herein, specify the presence of stated features, steps, operations, elements and/or components, but do not preclude the presence or addition of one or more other features, steps, operations, elements, components and/or groups thereof. The term “and/or” includes any and all combinations of one or more of the associated listed items. As used herein, “an element A is at a same level as element B” refers to at least one surface of element A that is coplanar with at least one surface of element B. As used herein, “an element A is at a lower level than element B” refers to at least one surface of element A that extends from a reference object by a smaller distance than element B extends from the same reference object. As used herein, “an element A is at a higher level than element B” refers to at least one surface of element A that extends from a reference object by a greater distance than element B extends from the same reference object. The term “connected” may be used herein to refer to a physical and/or electrical connection and may refer to a direct or indirect physical and/or electrical connection.

Example embodiments of the present disclosures will now be described more fully with reference to the accompanying drawings, in which example embodiments are shown. Like reference numerals in the drawings denote like elements, and thus their description will be omitted.

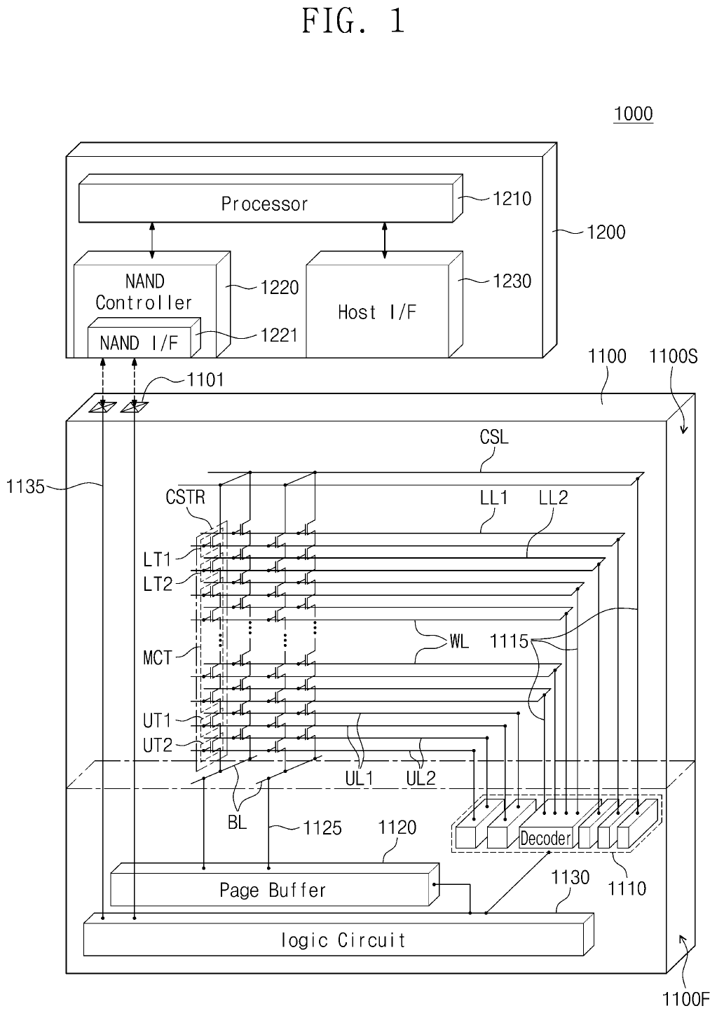

FIG. 1 is a diagram schematically illustrating an electronic system including a three-dimensional semiconductor memory device according to an embodiment of the present disclosure.

Referring to FIG. 1, an electronic system 1000 may include a three-dimensional semiconductor memory device 1100 and a controller 1200, which is electrically connected to the three-dimensional semiconductor memory device 1100. The electronic system 1000 may be a storage device including one or more three-dimensional semiconductor memory devices 1100 or an electronic device including the storage device. For example, the electronic system 1000 may be a solid state drive (SSD) device, a universal serial bus (USB), a computing system, a medical system, or a communication system, in which at least one three-dimensional semiconductor memory device 1100 is provided.

The three-dimensional semiconductor memory device 1100 may be a nonvolatile memory device (e.g., a three-dimensional NAND FLASH memory device to be described below). The three-dimensional semiconductor memory device 1100 may include a first region 1100F and a second region 1100S on the first region 1100F. However, in one variation, the first region 1100F may be disposed beside the second region 1100S. The first region 1100F may be a peripheral circuit region, which includes a decoder circuit 1110, a page buffer 1120, and a logic circuit 1130. The second region 1100S may be a memory cell region, which includes bit lines BL, a common source line CSL, word lines WL, first lines LL1 and LL2, second lines UL1 and UL2, and memory cell strings CSTR between the bit lines BL and the common source line CSL.

In the second region 1100S, each of the memory cell strings CSTR may include first transistors LT1 and LT2 adjacent to the common source line CSL, second transistors UT1 and UT2 adjacent to the bit lines BL, and a plurality of memory cell transistors MCT disposed between the first transistors LT1 and LT2 and the second transistors UT1 and UT2. The number of the first transistors LT1 and LT2 and the number of the second transistors UT1 and UT2 may be variously changed, according to embodiments. The memory cell strings CSTR may be positioned between the common source line CSL and the first region 1100F.

For example, the second transistors UT1 and UT2 may include a string selection transistor, and the first transistors LT1 and LT2 may include a ground selection transistor. The first lines LL1 and LL2 may serve as gate electrodes of the first transistors LT1 and LT2. The word lines WL may serve as gate electrodes of the memory cell transistors MCT, and the second lines UL1 and UL2 may serve as gate electrodes of the second transistors UT1 and UT2.

For example, the first transistors LT1 and LT2 may include a first erase control transistor LT1 and a ground selection transistor LT2, which are connected in series. For example, the second transistors UT1 and UT2 may include a string selection transistor UT1 and a second erase control transistor UT2, which are connected in series. At least one of the first and second erase control transistors LT1 and UT2 may be used for an erase operation of erasing data, which are stored in the memory cell transistors MCT, using a gate-induced drain leakage (GIDL) phenomenon.

The common source line CSL, the first lines LL1 and LL2, the word lines WL, and the second lines UL1 and UL2 may be electrically connected to the decoder circuit 1110 through first interconnection lines 1115, which are extended from the first region 1100F to the second region 1100S. The bit lines BL may be electrically connected to the page buffer 1120 through second interconnection lines 1125, which are extended from the first region 1100F to the second region 1100S.

In the first region 1100F, the decoder circuit 1110 and the page buffer 1120 may be configured to perform a control operation, which is performed on at least one memory cell transistor that is selected from the memory cell transistors MCT. The decoder circuit 1110 and the page buffer 1120 may be controlled by the logic circuit 1130. The three-dimensional semiconductor memory device 1100 may communicate with the controller 1200 through an input/output pad 1101, which is electrically connected to the logic circuit 1130. The input/output pad 1101 may be electrically connected to the logic circuit 1130 through an input/output interconnection line 1135, which is extended from the first region 1100F to the second region 1100S.

The controller 1200 may include a processor 1210, a NAND controller 1220, and a host interface 1230. In an embodiment, the electronic system 1000 may include a plurality of three-dimensional semiconductor memory devices 1100, which are controlled by the controller 1200.

The processor 1210 may control overall operations of the electronic system 1000 including the controller 1200. Based on a specific firmware, the processor 1210 may execute operations of controlling the NAND controller 1220 and accessing the three-dimensional semiconductor memory device 1100. The NAND controller 1220 may include a NAND interface 1221, which is used for communication with the three-dimensional semiconductor memory device 1100. The NAND interface 1221 may be used to transmit and receive control commands to control the three-dimensional semiconductor memory device 1100, data to be written in or read from the memory cell transistors MCT of the three-dimensional semiconductor memory device 1100, and so forth. The host interface 1230 may be configured to allow for communication between the electronic system 1000 and an external host. If a control command is provided from an external host through the host interface 1230, the processor 1210 may control the three-dimensional semiconductor memory device 1100 in response to the control command.

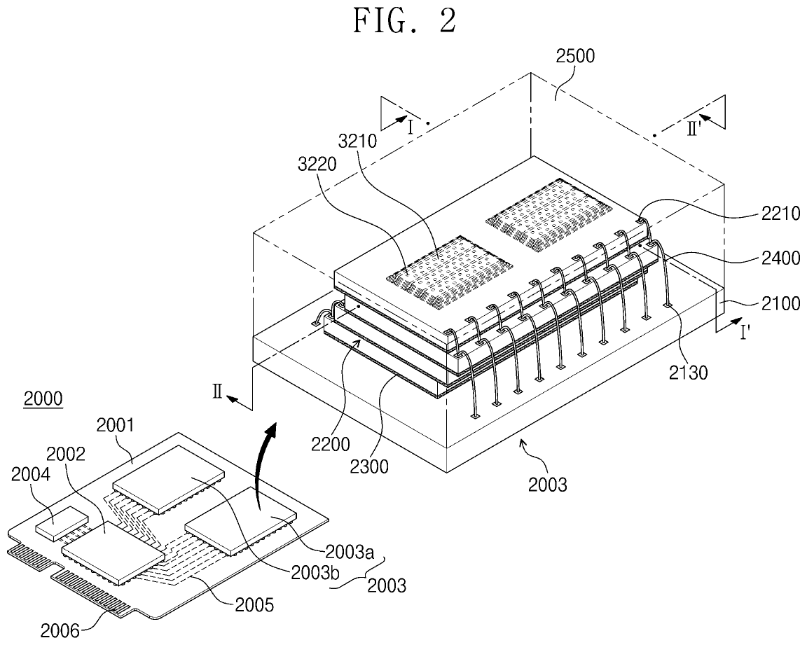

FIG. 2 is a perspective view schematically illustrating an electronic system including a three-dimensional semiconductor memory device according to an embodiment of the present disclosure.

Referring to FIG. 2, an electronic system 2000 may include a main substrate 2001 and a controller 2002, one or more semiconductor packages 2003, and a DRAM 2004, which are mounted on the main substrate 2001. The semiconductor package 2003 and the DRAM 2004 may be connected to the controller 2002 and to each other by interconnection patterns 2005, which are provided in the main substrate 2001.

The main substrate 2001 may include a connector 2006, which includes a plurality of pins coupled to an external host. In the connector 2006, the number and the arrangement of the pins may be changed depending on a communication interface between the electronic system 2000 and an external host. For example, the electronic system 2000 may communicate with the external host, in accordance with one of interfaces, such as universal serial bus (USB), peripheral component interconnect express (PCI-Express), serial advanced technology attachment (SATA), universal flash storage (UFS) M-PHY, or the like. In an embodiment, the electronic system 2000 may be driven by an electric power, which is supplied from the external host through the connector 2006. The electronic system 2000 may further include a power management integrated circuit (PMIC) that is used to separately supply the electric power, which is provided from the external host, to the controller 2002 and the semiconductor package 2003.

The controller 2002 may control a writing or reading operation on the semiconductor package 2003 and may improve an operation speed of the electronic system 2000.

The DRAM 2004 may be a buffer memory that is used to relieve technical difficulties caused by a difference in speed between the semiconductor package 2003, which serves as a data storage device, and an external host. In an embodiment, the DRAM 2004 in the electronic system 2000 may serve as a cache memory and may be used as a storage space, which is used to temporarily store data during a control operation on the semiconductor package 2003. In the case where the electronic system 2000 includes the DRAM 2004, the controller 2002 may further include a DRAM controller for controlling the DRAM 2004, in addition to a NAND controller for controlling the semiconductor package 2003.

The semiconductor package 2003 may include first and second semiconductor packages 2003a and 2003b, which are spaced apart from each other. Each of the first and second semiconductor packages 2003a and 2003b may be a semiconductor package including a plurality of semiconductor chips 2200. Each of the first and second semiconductor packages 2003a and 2003b may include a package substrate 2100, the semiconductor chips 2200, which are provided on the package substrate 2100, adhesive layers 2300, which are respectively disposed in bottom surfaces of the semiconductor chips 2200, connection structures 2400, which are used to electrically connect the semiconductor chips 2200 to the package substrate 2100, and a molding layer 2500, which is provided on the package substrate 2100 to cover the semiconductor chips 2200 and the connection structures 2400.

The package substrate 2100 may be a printed circuit board including package upper pads 2130. Each of the semiconductor chips 2200 may include input/output pads 2210. Each of the input/output pads 2210 may correspond to the input/output pad 1101 of FIG. 1. Each of the semiconductor chips 2200 may include gate stacks 3210 and memory channel structures 3220. Each of the semiconductor chips 2200 may include a three-dimensional semiconductor memory device, which will be described below.

The connection structures 2400 may be, for example, bonding wires, which are used to electrically connect the input/output pads 2210 to the package upper pads 2130. That is, in each of the first and second semiconductor packages 2003a and 2003b, the semiconductor chips 2200 may be electrically connected to each other in a bonding wire manner and may be electrically connected to the package upper pads 2130 of the package substrate 2100. In an embodiment, the semiconductor chips 2200 in each of the first and second semiconductor packages 2003a and 2003b may be electrically connected by penetration electrodes (e.g., through silicon vias), not by a wire bonding method using the connection structures 2400.

In one variation, the controller 2002 and the semiconductor chips 2200 may be included in a single package. In an embodiment, the controller 2002 and the semiconductor chips 2200 may be mounted on a separate interposer substrate, not on the main substrate 2001, and may be connected to each other through interconnection lines, which are provided in the interposer substrate.

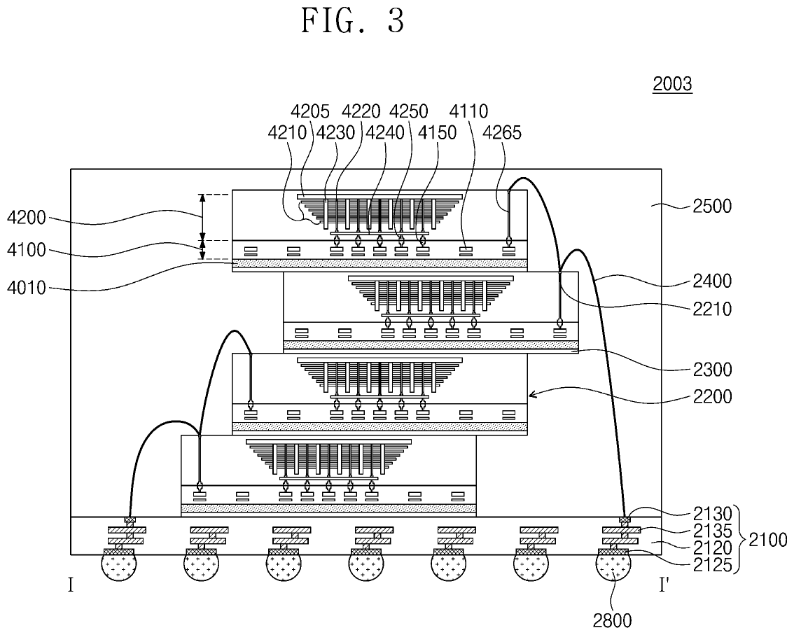

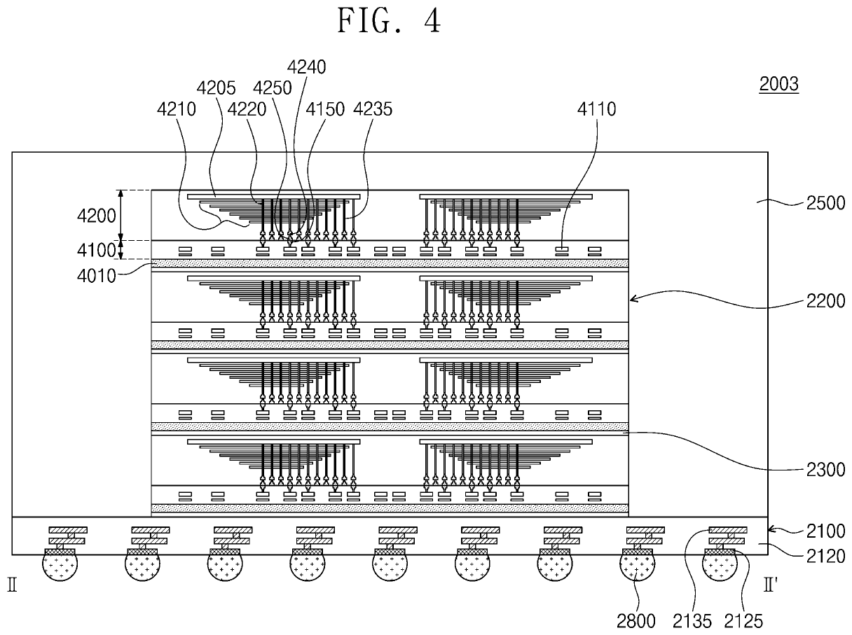

FIGS. 3 and 4 are sectional views, which are respectively taken along lines I-I′ and II-II′ of FIG. 2 to illustrate a semiconductor package including a three-dimensional semiconductor memory device according to an embodiment of the present disclosure.

Referring to FIGS. 3 and 4, the semiconductor package 2003 may include the package substrate 2100, the semiconductor chips 2200 on the package substrate 2100, and the molding layer 2500 covering the package substrate 2100 and the semiconductor chips 2200.

The package substrate 2100 may include a package substrate body portion 2120, upper pads 2130, which are provided on a top surface of the package substrate body portion 2120 and are exposed to the outside of the package substrate body portion 2120 near the top surface, lower pads 2125, which are provided on a bottom surface of the package substrate body portion 2120 or are exposed to the outside of the package substrate body portion 2120 near the bottom surface, and internal lines 2135, which are provided in the package substrate body portion 2120 to electrically connect the upper pads 2130 to the lower pads 2125. The upper pads 2130 may be electrically connected to the connection structures 2400. The lower pads 2125 may be connected to the interconnection patterns 2005 of the main substrate 2001 of the electronic system 2000, which is shown in FIG. 2, through conductive connecting portions 2800.

Referring to FIGS. 2 and 3, the semiconductor chips 2200 may be provided to have side surfaces, which are not aligned to each other, and other side surfaces, which are aligned to each other. The semiconductor chips 2200 may be electrically connected to each other through the connection structures 2400, which are provided in the form of bonding wires. Each of the semiconductor chips 2200 may include substantially the same elements.

Each of the semiconductor chips 2200 may include a semiconductor substrate 4010, a first structure 4100 on the semiconductor substrate 4010, and a second structure 4200 on the first structure 4100. The second structure 4200 may be connected to the first structure 4100 in a wafer bonding manner.

The first structure 4100 may include peripheral circuit interconnection lines 4110 and first bonding pads 4150. The second structure 4200 may include a common source line 4205, a gate stack 4210, which is provided between the common source line 4205 and the first structure 4100, memory channel structures 4220 and separation structures 4230, which are provided to extend into the gate stack 4210, and second bonding pads 4250, which are electrically and respectively connected to the memory channel structures 4220 and the word lines WL (e.g., see FIG. 1) of the gate stack 4210. For example, the second bonding pads 4250 may be electrically and respectively connected to the memory channel structures 4220 and the word lines WL through bit lines 4240, which are electrically connected to the memory channel structures 4220, and gate interconnection lines 4235, which are electrically connected to the word lines WL. The first bonding pads 4150 of the first structure 4100 and the second bonding pads 4250 of the second structure 4200 may be in contact with each other and may be coupled to each other. The coupling portions between the first bonding pads 4150 and the second bonding pads 4250 may be formed of or include, for example, copper (Cu).

Each of the semiconductor chips 2200 may further include the input/output pad 2210 and an input/output interconnection line 4265 below the input/output pad 2210. The input/output interconnection line 4265 may be electrically connected to some of the second bonding pads 4250 and some of the peripheral circuit interconnection lines 4110.

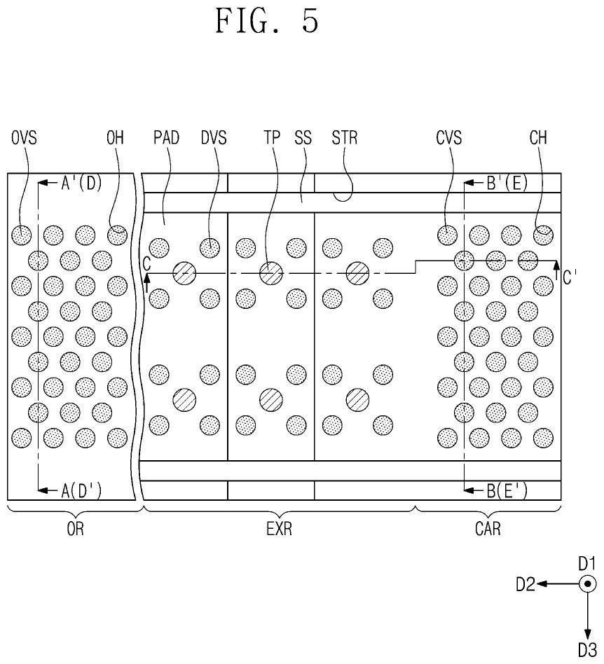

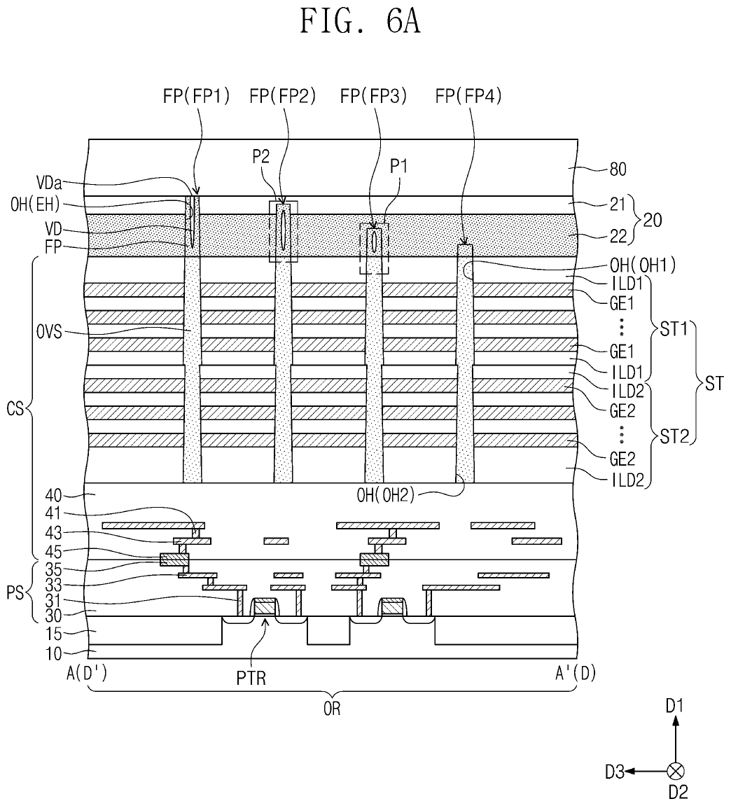

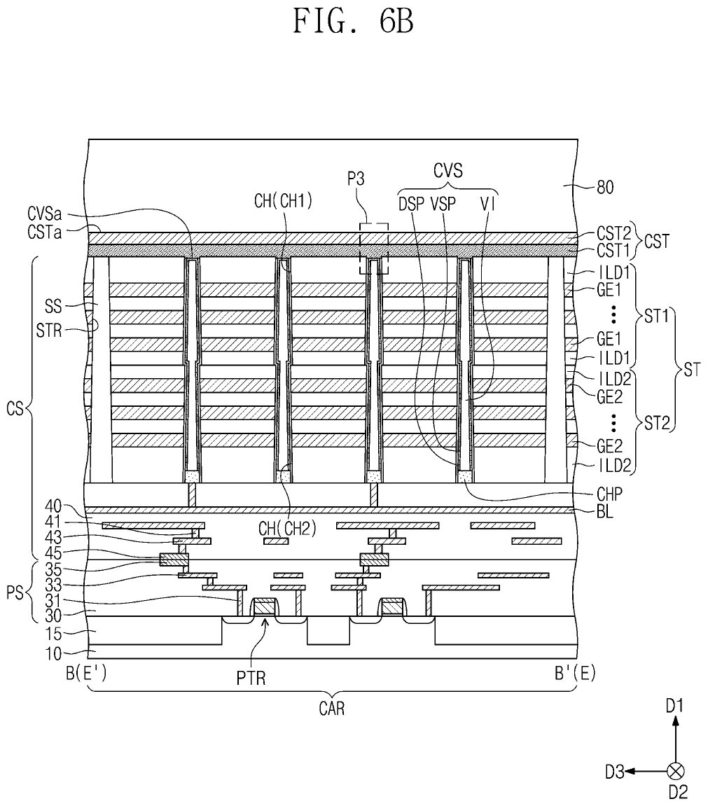

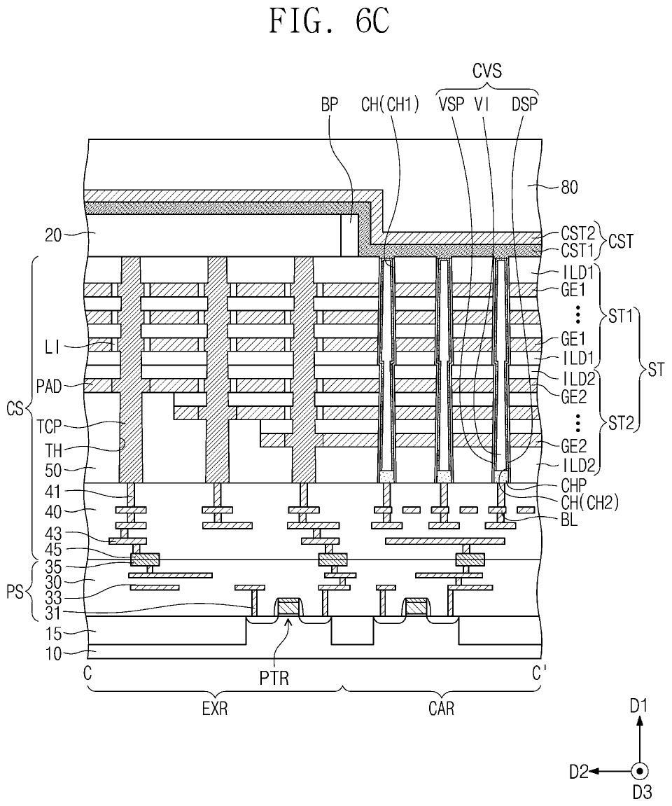

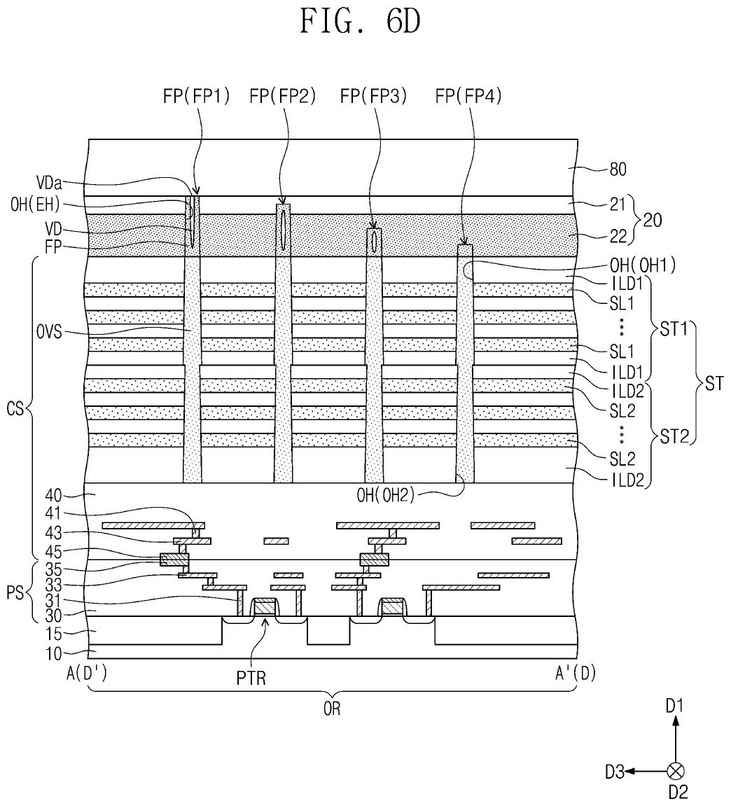

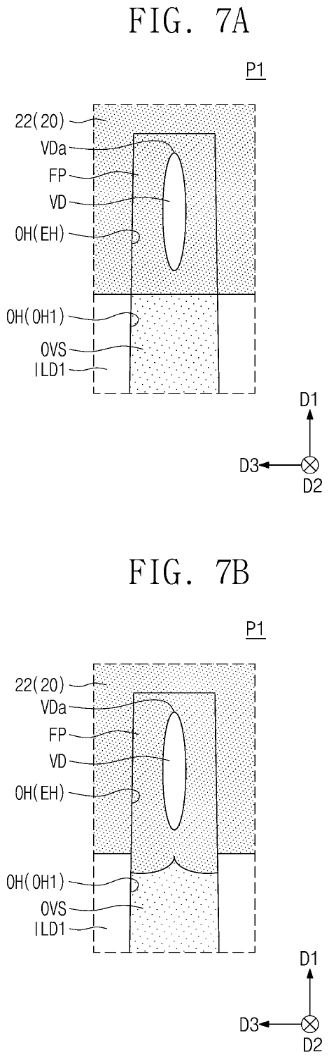

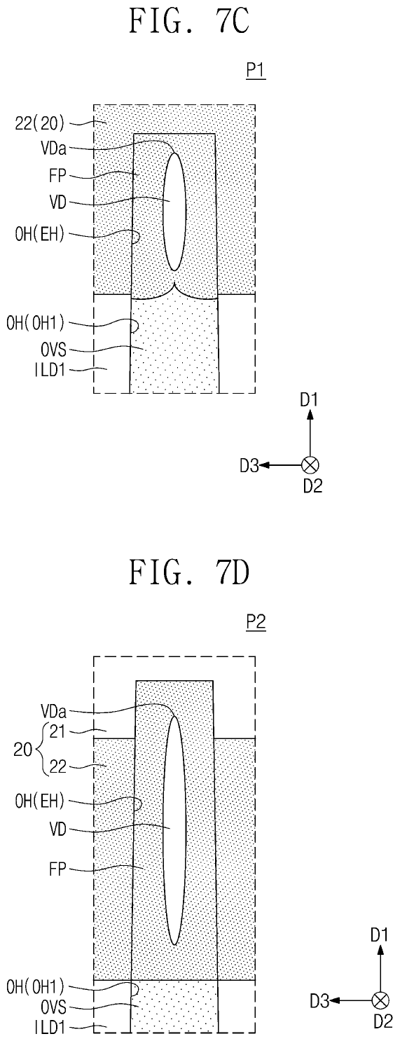

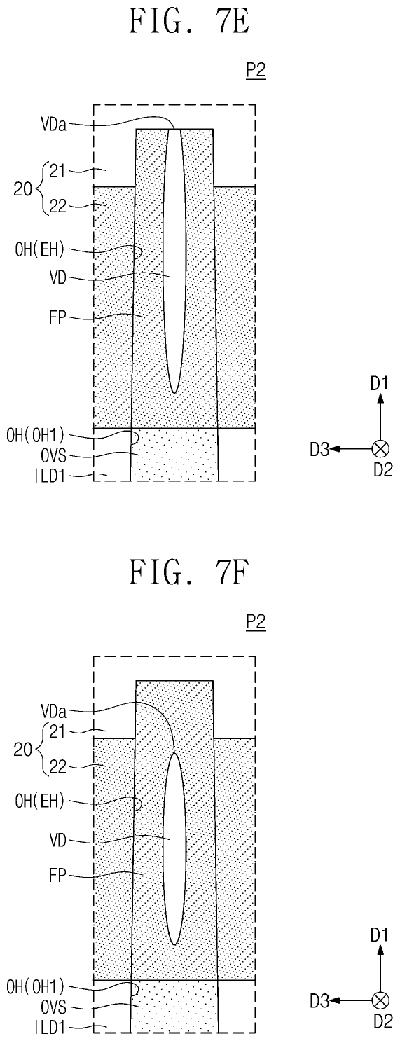

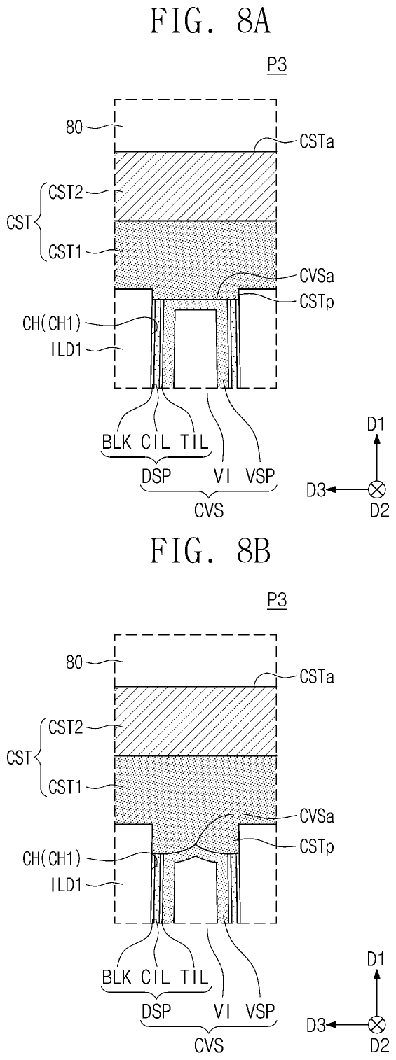

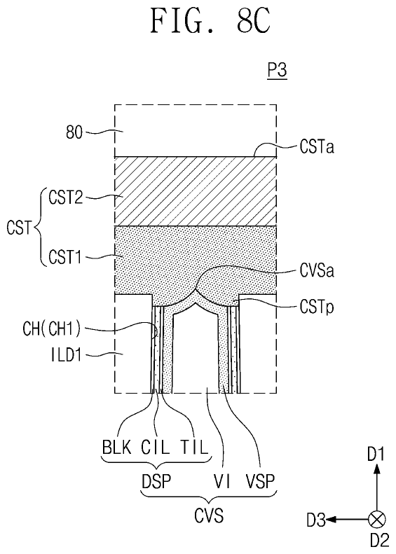

FIG. 5 is a plan view illustrating a three-dimensional semiconductor memory device according to an embodiment of the present disclosure. FIGS. 6A to 6C are sectional views taken along lines A-A′, B-B′, and C-C′ of FIG. 5. FIG. 6D is a sectional view taken along a line A-A′ of FIG. 5. FIGS. 7A to 7C are enlarged views corresponding to a portion P1 of FIG. 6A. FIGS. 7D to 7F are enlarged views corresponding to a portion P2 of FIG. 6A. FIGS. 8A to 8C are enlarged views corresponding to a portion P3 of FIG. 6B.

Referring to FIGS. 5 and 6A to 6D, the three-dimensional semiconductor memory device may include a peripheral circuit structure PS and a cell array structure CS, which are stacked on a peripheral substrate 10. The peripheral substrate 10 may correspond to the semiconductor substrate 4010 of FIGS. 3 and 4. The peripheral circuit structure PS may correspond to the first structure 4100 of FIGS. 3 and 4. The cell array structure CS may correspond to the second structure 4200 of FIGS. 3 and 4.

Since the cell array structure CS is coupled to the peripheral circuit structure PS, the three-dimensional semiconductor memory device may have an increased cell capacity per unit area. In an embodiment, the peripheral circuit structure PS and the cell array structure CS may be separately fabricated and then may be bonded to each other, and in this case, it may be possible to prevent peripheral transistors PTR, which will be described below, from being damaged by various thermal treatment processes and thereby to improve electrical and reliability characteristics of the three-dimensional semiconductor memory device.

In an embodiment, the peripheral substrate 10 may be a silicon substrate, a silicon germanium substrate, a germanium substrate, or a single crystalline epitaxial layer grown on a single-crystalline silicon substrate. The peripheral substrate 10 may have a top surface orthogonal to a first direction D1. The top surface of the peripheral substrate 10 may be parallel to a second direction D2 and a third direction D3, which are non-parallel to each other. For example, the first to third directions D1, D2, and D3 may be orthogonal to each other. A device isolation layer 15 may be provided in the peripheral substrate 10. The device isolation layer 15 may define an active region of the peripheral substrate 10.

The peripheral circuit structure PS may include peripheral transistors PTR on the peripheral substrate 10, peripheral contact plugs 31, peripheral circuit interconnection lines 33 electrically connected to the peripheral transistors PTR through the peripheral contact plugs 31, first bonding pads 35 electrically connected to peripheral circuit lines PCL, and a first insulating layer 30 enclosing these components. The peripheral transistors PTR may be provided on the active region of the peripheral substrate 10. The peripheral circuit interconnection lines 33 may correspond to the peripheral circuit interconnection lines 4110 of FIGS. 3 and 4, and the first bonding pads 35 may correspond to the first bonding pads 4150 of FIGS. 3 and 4.

As a height in the first direction D1 increases, widths of the peripheral contact plugs 31 in the second or third direction D2 or D3 may increase. The peripheral contact plugs 31 and the peripheral circuit interconnection lines 33 may be formed of or include at least one of conductive materials (e.g., metallic materials).

In an embodiment, the peripheral transistors PTR may constitute the decoder circuit 1110, the page buffer 1120, and the logic circuit 1130 of FIG. 1. Peripheral circuit lines PCL and the first bonding pads 35 may be electrically connected to the peripheral transistors PTR through peripheral contact plugs PCP. In an embodiment, each of the peripheral transistors PTR may be an NMOS transistor or a PMOS transistor.

The first insulating layer 30 may be provided on the peripheral substrate 10. The first insulating layer 30 may cover or overlap the peripheral transistors PTR, the peripheral contact plugs 31, and the peripheral circuit interconnection lines 33 on the peripheral substrate 10. The first insulating layer 30 may have a multi-layered structure including a plurality of insulating layers. In an embodiment, the first insulating layer 30 may be formed of or include at least one of silicon oxide, silicon nitride, silicon oxynitride, or low-k dielectric materials. The first insulating layer 30 may not cover or overlap top surfaces of the first bonding pads 35. A top surface of the first insulating layer 30 may be substantially coplanar with the top surfaces of the first bonding pads 35.

The cell array structure CS may be provided on the peripheral circuit structure PS. The cell array structure CS may include second bonding pads 45, bit lines BL, and a stack ST. The second bonding pads 45, the bit lines BL, and the stack ST may correspond to the second bonding pads 4250, the bit lines 4240, and the gate stack 4210, respectively, of FIGS. 3 and 4.

The cell array structure CS may include a cell array region CAR, a cell array extension region EXR, and an outer region OR. The cell array extension region EXR and the outer region OR may be extended from the cell array region CAR in one of the second and third directions D2 and D3 or opposite directions thereof.

The second bonding pads 45, connection contact plugs 41, connection circuit interconnection lines 43, and a second insulating layer 40 enclosing these components may be provided on the first insulating layer 30. Here, the second bonding pads 45 may be in contact with the first bonding pads 35 of the peripheral circuit structure PS, and the connection circuit interconnection lines 43 may be electrically connected to the second bonding pads 45 through the connection contact plugs 41.

The second insulating layer 40 may have a multi-layered structure including a plurality of insulating layers. In an embodiment, the second insulating layer 40 may be formed of or include at least one of silicon oxide, silicon nitride, silicon oxynitride, or low-k dielectric materials.

As a height in the first direction D1 increases, widths of the connection contact plugs 41 in the second or third direction D2 or D3 may decrease. The connection contact plugs 41 and the connection circuit interconnection lines 43 may be formed of or include at least one conductive material (e.g., metallic materials).

Some of the connection contact plugs 41 may connect the bit lines BL to cell vertical structures CVS, which will be described below. In an embodiment, each of the bit lines BL may be extended in the third direction D3 and may be spaced apart from each other in the second direction D2. The bit lines BL may be formed of or include at least one conductive material (e.g., metallic materials).

The second insulating layer 40 may not cover or overlap bottom surfaces of the second bonding pads 45. A bottom surface of the second insulating layer 40 may be substantially coplanar with the bottom surfaces of the second bonding pads 45. A bottom surface of each of the second bonding pads 45 may be in direct contact with a top surface of each of the first bonding pads 35. The first and second bonding pads 35 and 45 may be formed of or include at least one metallic material (e.g., copper (Cu), tungsten (W), aluminum (Al), nickel (Ni), or tin (Sn)). In an embodiment, the first and second bonding pads 35 and 45 may be formed of or include copper (Cu). The first and second bonding pads 35 and 45 may be connected to each other without any interface therebetween to form a single object. The side surfaces of the first and second bonding pads 35 and 45 are illustrated as being aligned with each other, but the present disclosure is not limited to this example. For example, the side surfaces of the first and second bonding pads 35 and 45 may be spaced apart from each other, when viewed in a plan view.

The stack ST and a third insulating layer 50 may be provided on the second insulating layer 40. The third insulating layer 50 may be provided to enclose or at least partially surround the stack ST. The third insulating layer 50 may include a plurality of insulating layers having a multi-layered structure. The third insulating layer 50 may be formed of or include at least one of silicon oxide, silicon nitride, silicon oxynitride, or low-k dielectric materials.

In an embodiment, a plurality of stacks ST may be provided. In an embodiment, the stacks ST may be extended in the second direction D2 and may be spaced apart from each other in the third direction D3, when viewed in a plan view. The stacks ST may be spaced apart from each other in the third direction D3 by a separation trench STR, which will be described below. Hereinafter, just one stack ST will be described for brevity's sake, but the other stacks ST may also have substantially the same features as described below.

The stack ST may include a first stack ST1 and a second stack ST2. The first stack ST1 may include first interlayer insulating layers ILD1 and first gate electrodes GE1, which are alternately stacked on top of each other, and the second stack ST2 may include second interlayer insulating layers ILD2 and second gate electrodes GE2, which are alternately stacked on top of each other (e.g., see FIGS. 6A to 6C).

The first stack ST1 may be provided on the peripheral substrate 10, and the second stack ST2 may be provided between the first stack ST1 and the peripheral substrate 10. More specifically, the second stack ST2 may be provided on a bottom surface of the lowermost one of the first interlayer insulating layers ILD1 of the first stack ST1. The uppermost one of the second interlayer insulating layers ILD2 of the second stack ST2 may be in contact with the lowermost one of the first interlayer insulating layers ILD1 of the first stack ST1, but the present disclosure is not limited to this example. For example, a single interlayer insulating layer may be provided between the uppermost one of the second gate electrodes GE2 of the second stack ST2 and the first gate electrodes GE1 of the first stack ST1.

The first and second gate electrodes GE1 and GE2 may be formed of or include at least one of, for example, doped semiconductor materials (e.g., doped silicon and so forth), metallic materials (e.g., tungsten, copper, aluminum, and so forth), conductive metal nitrides (e.g., titanium nitride, tantalum nitride, and so forth), or transition metals (e.g., titanium, tantalum, and so forth). The first and second interlayer insulating layers ILD1 and ILD2 may be formed of or include at least one of silicon oxide, silicon nitride, silicon oxynitride, or low-k dielectric materials. For example, the first and second interlayer insulating layers ILD1 and ILD2 may be formed of or include high density plasma (HDP) oxide or tetraethyl orthosilicate (TEOS).

In an embodiment, a third stack may further be provided between the second stack ST2 and the peripheral substrate 10, although not shown. The third stack may be provided to have substantially the same or similar features as the first stack ST1 and the second stack ST2.

The stack ST on the cell array extension region EXR may have a staircase structure in the second direction D2. For example, a thickness of the stack ST, which is measured in the first direction DI on the cell array extension region EXR, may decrease as a distance from the cell array region CAR increases. Lengths of the first and second gate electrodes GE1 and GE2 in the second direction D2 may increase as a distance from the peripheral substrate 10 increases. In the first and second gate electrodes GE1 and GE2, the lowermost one of the second gate electrodes GE2 may have the smallest length, and the uppermost one of the first gate electrodes GE1 may have the largest length. Side surfaces of the first and second gate electrodes GE1 and GE2 may be spaced apart from each other in the second direction D2 by specific distance, when viewed in a plan view.

Each of the first and second gate electrodes GE1 and GE2 may include a pad portion PAD, which is an end portion in the second direction D2. The pad portion PAD may be a portion of each of the first and second gate electrodes GE1 and GE2 that constitute the staircase structure of the stack ST. In each of the first and second gate electrodes GE1 and GE2, a thickness of the pad portion PAD in the first direction DI may be equal to or different from thicknesses of other portions. For example, in each of the first and second gate electrodes GE1 and GE2, the thickness of the pad portion PAD in the first direction DI may be larger than thicknesses of the other portions.

The first and second interlayer insulating layers ILD1 and ILD2 may be provided between the first and second gate electrodes GE1 and GE2, and each of these components may have a side surface that is aligned to one of the first and second gate electrodes GE1 and GE2 placed on or below thereof. That is, similar to the first and second gate electrodes GE1 and GE2, lengths of the first and second interlayer insulating layers ILD1 and ILD2 in the second direction D2 may increase as a distance from the peripheral substrate 10 increases.

In an embodiment, the stack ST may further include sacrificial layers SL1 and SL2 on the outer region OR (e.g., see FIG. 6D). In the fabrication method to be described below, the first and second gate electrodes GE1 and GE2 may be formed in empty regions, which are formed by removing the sacrificial layers SL1 and SL2. However, portions of the first and second sacrificial layers may not be removed, and thus, such portions of the first and second sacrificial layers may remain in a final structure of the three-dimensional semiconductor memory device. The sacrificial layers SL1 and SL2 may include a material having an etch selectivity with respect to the first and second interlayer insulating layers ILD1 and ILD2. For example, the sacrificial layers SL1 and SL2 may be formed of or include silicon nitride.

A base pattern 20 may be provided on the cell array structure CS. As an example, the base pattern 20 may be provided on the cell array extension region EXR and the outer region OR. In an embodiment, a boundary separation pattern BP may be provided between the base pattern 20 and the cell array region CAR, when viewed in a plan view. The base pattern 20 may include an upper base pattern 21 (also referred to herein as an “upper base pattern portion 21”) and a lower base pattern 22 (also referred to herein as a “lower base pattern portion 22”), which is provided between the cell array structure CS and the upper base pattern 21. The upper base pattern 21 may be or include a remaining portion of a second cell array substrate 120, which is not removed in a process of fabricating the three-dimensional semiconductor memory device. The lower base pattern 22 may be or include a remaining portion of a third cell array substrate 130, which is not removed in a process of fabricating the three-dimensional semiconductor memory device. As an example, the upper base pattern 21 may be formed of or include an insulating material (e.g., silicon oxide). In an embodiment, the lower base pattern 22 may be formed of or include a semiconductor material (e.g., silicon).

Outer holes OH may be provided on the outer region OR to extend into the cell array structure CS. Each of the outer holes OH may be formed to extend into at least one of the stack ST and the third insulating layer 50 in the first direction D1. In an embodiment, each of the outer holes OH may include a first outer hole OH1 and a second outer hole OH2. An outer vertical structure OVS may be at least partially in the first outer hole OH1 and the second outer hole OH2. The first outer hole OH1 and the second outer hole OH2 may be provided to have the same or similar features as a first channel hole CH1 and a second channel hole CH2, which will be described below. The first and second outer holes OH1 and OH2 may be connected to each other and may have diameters, which are different from each other, near a boundary therebetween. In detail, a diameter of an upper portion of the second outer hole OH2 may be smaller than a diameter of a lower portion of the first outer hole OH1. The first and second outer holes OH1 and OH2 may form a stepwise structure near the boundary therebetween. However, the present disclosure is not limited to this example, and in an embodiment, three or more outer holes may be provided to form the stepwise structures near two or more boundaries. Alternatively, the outer holes OH may be provided to have a flat side surface without a stepwise portion.

In an embodiment, at least a portion of the outer holes OH may further include an extension hole EH, which is extended from the first outer hole OH1 into the base pattern 20. The extension hole EH may be provided at a level that is higher than the uppermost end of the cell array structure CS (e.g., the top surface of the uppermost one of the first interlayer insulating layers ILD1). In an embodiment, the extension hole EH may extend through the entirety or a portion of the base pattern 20.

The outer vertical structure OVS may be provided on the outer region OR to extend into the cell array structure CS in the first direction D1. The outer vertical structure OVS may extend into at least one of the stack ST and the third insulating layer 50 in the first direction D1. In an embodiment, a plurality of outer vertical structures OVS may be provided. Each of the outer vertical structures OVS may be provided in at least a portion of the first outer hole OH1 and the second outer hole OH2.

The outer vertical structure OVS may be a single layer, which is made of a single material, or a composite layer including two or more materials. As an example, the outer vertical structure OVS may be formed of one or more insulating materials. As another example, the outer vertical structure OVS may be formed of a semiconductor material. Each of the outer vertical structures OVS may correspond to one of various elements constituting the three-dimensional semiconductor memory device. As an example, the outer vertical structure OVS may be used as a part of a test element group (TEG). As another example, the outer vertical structure OVS may be a dummy pattern that is at least partially in the outer hole OH. However, the present disclosure is not limited to this example.

A filling pattern FP may be provided on the outer vertical structure OVS. In an embodiment, a plurality of filling patterns FP may be provided on the outer vertical structures OVS, respectively. The filling pattern FP may be at least partially in the extension hole EH. The filling pattern FP may be formed through a selective epitaxial process (SEG) process. In an embodiment, the filling pattern FP may be formed of or include silicon.

The uppermost end of the filling pattern FP may be located at various levels and the location of the uppermost end of the filling pattern FP may be based on the position of the uppermost end of the extension hole EH. In an embodiment, and as shown in FIG. 6A, the filling pattern FP may include first, second, third, and fourth filling patterns FP1, FP2, FP3, and FP4, and the uppermost ends of the first, second, third, and fourth filling patterns FP1, FP2, FP3, and FP4 may be located at different levels from each other. The uppermost end of the first filling pattern FP1 may be located at the same level as the top surface of the base pattern 20 (e.g., the top surface of the upper base pattern 21). The uppermost end of the second filling pattern FP2 may be located at a level that is lower than the top surface of the upper base pattern 21 and is higher than the top surface of the lower base pattern 22. The uppermost end of the third filling pattern FP3 may be located at a level lower than the top surface of the lower base pattern 22, and the uppermost end of the fourth filling pattern FP4 may be located at a level lower than the uppermost end of the third filling pattern FP3.

A void VD may be provided in the filling pattern FP. The void VD may be an empty space, which is formed in the extension hole EH when a portion of the extension hole is not filled with the filling pattern FP in a SEG process for forming the filling pattern FP. The void VD may be enclosed by the filling pattern FP. In an embodiment, a plurality of voids VD may be formed in the filling patterns FP, respectively. The void VD may not be formed in some of the filling patterns FP. As an example, the fourth filling pattern FP4 may be formed in the extension hole EH, which has a relatively small volume, and in this case, the extension hole EH may be completely filled with the fourth filling pattern FP4 and may have a void-free structure.

The uppermost end VDa of the void VD may be located at a level that is lower than or equal to the top surface of the base pattern 20. The uppermost end VDa of the void VD may be defined by various elements. As an example, the uppermost end VDa of the void VD in the first filling pattern FP1 may be defined by a protection layer 80 that is described below, and the protection layer 80 may be exposed to the uppermost end VDa of the void VD. As another example, the uppermost end VDa of the void VD in the second or third filling pattern FP2 or FP3 may be defined by the filling pattern FP. As yet another example, the uppermost end VDa of the void VD in the second filling pattern FP2 may be defined by the base pattern 20, and the base pattern 20 may be exposed to the uppermost end VDa of the void VD (e.g., see FIG. 7E).

In the outer hole OH, the filling pattern FP, the outer vertical structure OVS, and the void VD may have various shapes. Hereinafter, the structural features between these components according to some embodiments of the present disclosures will be described with reference to FIGS. 7A to 7F. However, the present disclosure is not limited to the embodiments to be described below.

Referring to FIGS. 7A to 7C, a top surface of the outer vertical structure OVS may have various profiles. In an embodiment, the top surface of the outer vertical structure OVS may have a flat shape, as shown in FIG. 7A. Accordingly, a bottom surface of the filling pattern FP may also have a flat shape. In another embodiment, the top surface of the outer vertical structure OVS may have an uneven shape, as shown in FIGS. 7B and 7C. Thus, the bottom surface of the filling pattern FP may also have an uneven shape. As used herein, “uneven shape” may refer to a shape that is not flat.

Furthermore, the uppermost end of the outer vertical structure OVS may be provided at various levels. In an embodiment, as shown in FIG. 7A, the uppermost end of the outer vertical structure OVS may be located at the same level as the top surface of the uppermost one of the first interlayer insulating layers ILD1. In another embodiment, as shown in FIG. 7B, the uppermost end of the outer vertical structure OVS may be located at a level lower than the top surface of the uppermost one of the first interlayer insulating layers ILD1. In another embodiment, and as shown in FIG. 7C, the uppermost end of the outer vertical structure OVS may be located at a level higher than the top surface of the uppermost one of the first interlayer insulating layers ILD1.

Referring to FIGS. 7D to 7F, the uppermost end of the void VD may be located at various levels. In an embodiment, and as shown in FIGS. 7D and 7E, the uppermost end VDa of the void VD may be located at a level higher than the top surface of the lower base pattern 22. In another embodiment, and as shown in FIG. 7F, the uppermost end VDa of the void VD may be located at a level lower than the top surface of the lower base pattern 22. In one variation, the uppermost end VDa of the void VD may be located at the same level as the top surface of the lower base pattern 22.

Referring back to FIGS. 5 to 6C, channel holes CH may be provided to extend into the cell array structure CS in the cell array region CAR and the cell array extension region EXR. Each of the channel holes CH may be provided to extend into at least one of the stack ST and the third insulating layer 50 in the first direction DI. As an example, each of the channel holes CH may include the first channel hole CH1 extending into the first stack ST1 and the second channel hole CH2 extending into the second stack ST2. As a distance from the peripheral substrate 10 increases, a width of each of the first and second channel holes CH1 and CH2 in the second and/or third direction D2 and/or D3 may decrease. The first and second channel holes CH1 and CH2 may be connected to each other and may have different diameters from each other near a boundary region where they are connected to each other. In detail, a diameter of an upper portion of the second channel hole CH2 may be smaller than a diameter of a lower portion of a first channel hole CH1. The first and second channel holes CH1 and CH2 may form a stepwise structure near the boundary region. However, the present disclosure is not limited to this example, and in an embodiment, three or more channel holes may be provided to form the stepwise structures near two or more boundaries. Alternatively, the channel holes may be provided to have a flat side surface without a stepwise portion.

In the cell array region CAR, the cell vertical structures CVS may be provided to extend into the stack ST in the first direction D1 and to be at least partially in the channel hole CH. The cell vertical structures CVS may correspond to the memory channel structures 4220 of FIGS. 3 and 4. Each of the cell vertical structures CVS may include a channel pad CHP that is adjacent to the second insulating layer 40. The cell vertical structures CVS may be electrically connected to the connection contact plug 41 and the bit lines BL through the channel pads CHP. In the cell array extension region EXR, dummy vertical structures DVS may be provided to extend into at least one of the stack ST and the third insulating layer 50 in the first direction D1 and to be at least partially in the channel hole CH. In an embodiment, each of the bottom surfaces of the cell and dummy vertical structures CVS and DVS may have a circular, elliptical, or bar shape.

Each of the cell vertical structures CVS may include a data storage pattern DSP conformally covering or overlapping an inner side surface of the channel hole CH, a vertical semiconductor pattern VSP conformally covering or overlapping a side surface of the data storage pattern DSP, and a gapfill insulating pattern VI, which is enclosed by the vertical semiconductor pattern VSP and the channel pad CHP and is at least partially in an internal space of the channel hole CH. The vertical semiconductor pattern VSP may be provided between the data storage pattern DSP and the gapfill insulating pattern VI and between the data storage pattern DSP and the channel pad CHP. The vertical semiconductor pattern VSP may have a top-closed pipe or nonlinear structure. The data storage pattern DSP may be shaped like a pipe with an open top end. The vertical semiconductor pattern VSP may be formed of or include at least one of doped semiconductor materials or undoped or intrinsic semiconductor materials and may have a poly-crystalline or single-crystalline structure. The channel pad CHP may be formed of or include a doped semiconductor material or a conductive material.

A source structure CST may be provided on the cell array structure CS. The source structure CST may be extended in the second direction D2 and the third direction D3. The source structure CST may be in contact with the stack ST in the cell array region CAR. The source structure CST may be provided on the base pattern 20 in the cell array extension region EXR. In an embodiment, the source structure CST may further be provided on the base pattern 20 in the outer region OR. The source structure CST may correspond to the common source line 4205 of FIGS. 3 and 4.

The source structure CST may include a first source layer CST1 and a second source layer CST2 on the first source layer CST1. The first source layer CST1 may be in contact with the cell vertical structures CVS. The first source layer CST1 may be formed of or include a semiconductor material (e.g., doped silicon) that is doped with impurities of a first conductivity type (e.g., n-type). The second source layer CST2 may be formed of or include at least one of, for example, metallic materials (e.g., Ti, Mo, W, Cu, Al, Ta, Ru, Ir, Co, Pt, Au, and Ag), metal nitride materials (e.g., nitrides of Ti, Mo, W, Cu, Al, Ta, Ru, Ir, Co, Pt, Au, and Ag, titanium silicon nitride (e.g., TiSiN), titanium aluminum nitride (e.g., TiAlN), and tantalum aluminum nitride (e.g., TaAlN)), or conductive oxide materials (e.g., PtO, RuO₂, IrO₂, SRO (SrRuO₃), BSRO ((Ba,Sr) RuO₃), CRO (CaRuO₃), or LSCo). In an embodiment, a metal silicide layer may be further provided between the first source layer CST1 and the second source layer CST2.

Referring to FIGS. 8A to 8C, the data storage pattern DSP of the cell vertical structure CVS may include a blocking insulating layer BLK, a charge storing layer CIL, and a tunneling insulating layer TIL, which are sequentially stacked on the inner side surface of the channel hole CH. The charge storing layer CIL may be interposed between the blocking insulating layer BLK and the tunneling insulating layer TIL. The blocking insulating layer BLK, the charge storing layer CIL, and the tunneling insulating layer TIL may be extended along the inner side surface of the channel hole CH, between the stack ST and the vertical semiconductor pattern VSP. The data storage pattern DSP may cover or overlap the side surface of the vertical semiconductor pattern VSP but may not cover/overlap the top surface of the vertical semiconductor pattern VSP.

In an embodiment, the Fowler-Nordheim (FN) tunneling phenomenon, which is caused by a voltage difference between the vertical semiconductor pattern VSP and the first and second gate electrodes GE1 and GE2, may be used to store or change data in the data storage pattern DSP. For example, the blocking insulating layer BLK and the tunneling insulating layer TIL may be formed of or include silicon oxide, and the charge storing layer CIL may be formed of or include at least one of silicon nitride or silicon oxynitride.

The cell vertical structure CVS may be connected to the source structure CST. The first source layer CST1 may be in contact with a top surface of the cell vertical structure CVS. The top surface of the cell vertical structure CVS may have various profiles. In an embodiment, the top surface of the cell vertical structure CVS may have a flat shape, as shown in FIG. 8A. In another embodiment, the top surface of the cell vertical structure CVS may have an uneven shape, as shown in FIGS. 8B and 8C.

The lowermost end of the top surface of the cell vertical structure CVS may be located at a level lower than the top surface of the uppermost one of the first interlayer insulating layers ILD1. The uppermost end CVSa of the cell vertical structure CVS may be located at a level lower than a top surface CSTa of the source structure CST. In an embodiment, as shown in FIGS. 8A and 8B, the uppermost end CVSa of the cell vertical structure CVS may be located at a level lower than the top surface of the uppermost one of the first interlayer insulating layers ILD1. In another embodiment, as shown in FIG. 8C, the uppermost end CVSa of the cell vertical structure CVS may be located at a level higher than the top surface of the uppermost one of the first interlayer insulating layers ILD1.

The source structure CST may include a protruding portion CSTp extending into the cell array structure CS. Accordingly, a bottom surface of the source structure CST may have an uneven structure. The protruding portion CSTp of the source structure CST may be provided on the cell vertical structure CVS. The protruding portion CSTp of the source structure CST may be buried in the channel hole CH. The protruding portion CSTp of the source structure CST may cover or overlap a portion of a side surface of the uppermost one of the first interlayer insulating layers ILD1. The lowermost end of the source structure CST may be located at a level lower than the top surface of the uppermost one of the first interlayer insulating layers ILD1.

Referring back to FIGS. 5 to 6C, penetration contact plugs TCP may be provided in penetration holes TH, which are formed to extend into the cell array structure CS in the cell array extension region EXR. Each of the penetration contact plugs TCP may be in contact with the pad portion PAD of a corresponding one of the gate electrodes GE1 and GE2 and thus may be connected to the corresponding one of the gate electrodes GE1 and GE2. Each of the penetration contact plugs TCP may be spaced apart from disconnected ones of the gate electrodes GE1 and GE2 by a sidewall insulating pattern LI. As a distance from the peripheral substrate 10 increases, a width of each of the penetration contact plugs TCP in the second direction D2 and/or the third direction D3 may decrease. In another embodiment, the penetration contact plug TCP may be provided in the penetration holes TH, which have stepwise portions near one or more boundaries, similar to the cell vertical structure CVS. The penetration contact plug TCP may be formed of or include at least one metallic material (e.g., Ti, Mo, W, Cu, Al, Ta, Ru, Ir, Co, Pt, Au, and Ag).

The separation trench STR may be extended in the second direction D2. The separation trench STR may separate the stacks ST from each other in the third direction D3. The separation trench STR may be extended from the cell array region CAR toward the cell array extension region EXR. As a distance from the peripheral substrate 10 increases, a width of the separation trench STR in the third direction D3 may decrease.

A separation pattern SS may be at least partially in an inner space of the separation trench STR. The separation pattern SS may correspond to the separation structures 4230 of FIGS. 3 and 4. A side surface of the separation pattern SS may be in contact with at least a portion of the first and second gate electrodes GE1 and GE2 and the first and second interlayer insulating layers ILD1 and ILD2 of the stack ST. The separation pattern SS may be provided between the stacks ST to separate the stacks ST from each other in the third direction D3. A bottom surface of the separation pattern SS may be placed at the same level as a bottom surface of the cell vertical structure CVS, but the present disclosure is not limited to this example. In an embodiment, the separation patterns SS may be formed of or include at least one of silicon oxide, silicon nitride, silicon oxynitride, or low-k dielectric materials.

The protection layer 80 may be provided on the cell array structure CS. The protection layer 80 may cover or overlap the base pattern 20 and the source structure CST. The protection layer 80 may be a single layer, which is made of a single material, or a composite layer including two or more materials. As an example, the protection layer 80 may include a silicon oxide layer, a silicon nitride layer, and a polyimide-based layer (e.g., of photosensitive polyimide (PSPI)), which are sequentially stacked, but the present disclosure is not limited to this example. In one variation, the protection layer 80 may have an opening, which is formed to expose some of the input/output pads.

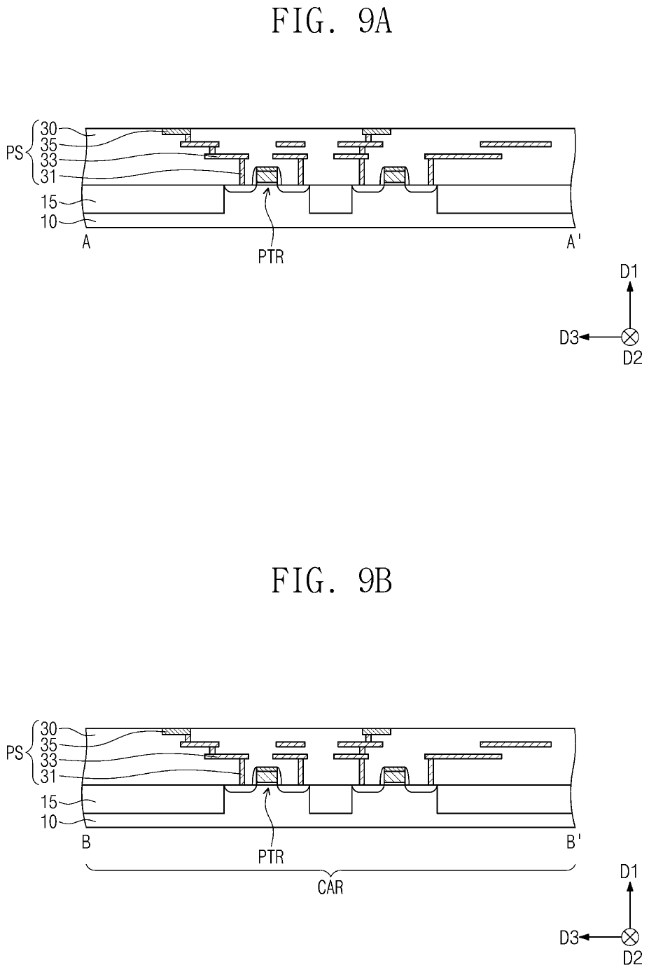

FIGS. 9A to 13B are sectional views illustrating a method of fabricating a three-dimensional semiconductor memory device according to an embodiment of the present disclosure. Hereinafter, the fabrication method according to an embodiment of the present disclosure will be described in more detail with reference to FIGS. 9A to 13B. For concise description, a previously described element may be identified by the same reference number without repeating a corresponding description thereof.

Referring to FIGS. 5, 9A, and 9B, the peripheral circuit structure PS may be formed on the peripheral substrate 10. The formation of the peripheral circuit structure PS may include forming the device isolation layer 15 in the peripheral substrate 10, forming the peripheral transistors PTR on the active region of the peripheral substrate 10 defined by the device isolation layer 15, and forming the peripheral contact plugs 31, the peripheral circuit interconnection lines 33, the first bonding pads 35, which are electrically connected to the peripheral transistors PTR, and the first insulating layer 30 covering and overlapping these components.

The top surfaces of the first bonding pads 35 may be substantially coplanar with the top surface of the first insulating layer 30. In an embodiment, a planarization process may be performed to form the substantially coplanar surfaces. For example, the planarization process may be performed using a chemical mechanical polishing (CMP) process or an etch-back process.

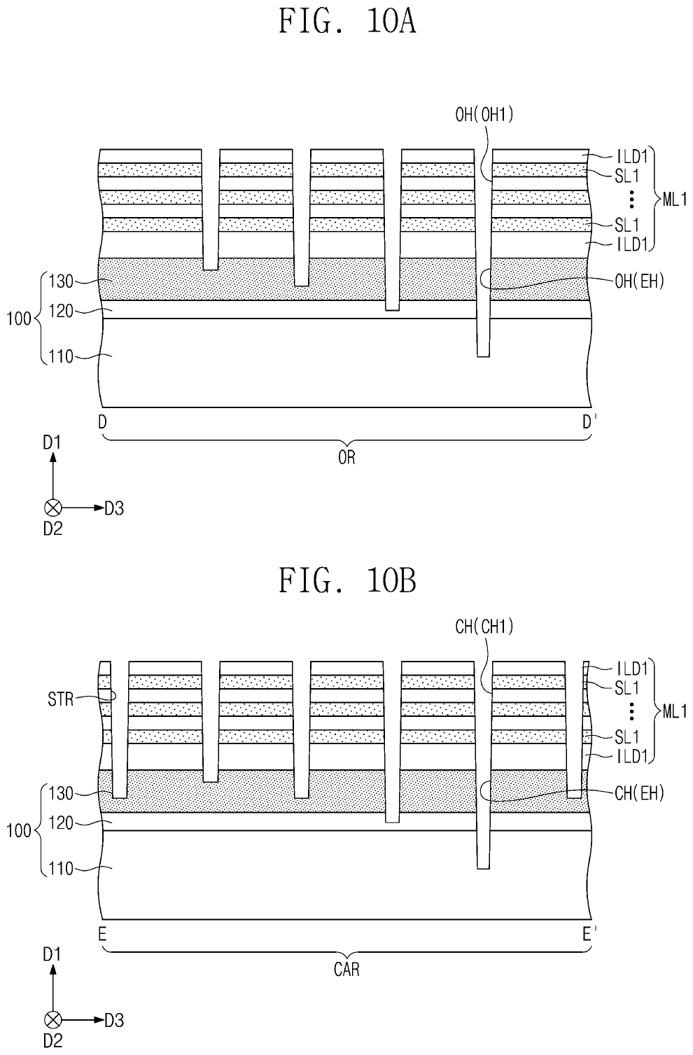

In the following description of FIGS. 10A to 12B, the term ‘top surface’ will be used to represent a ‘bottom surface’ of a fabrication-completed structure of the three-dimensional semiconductor memory device described with reference to FIGS. 6A to 6C, the term ‘bottom surface’ will be used to represent a ‘top surface’ of the fabrication-completed structure. Similarly, the terms ‘upper portion’ and ‘lower portion’ may be used to represent a ‘lower portion’ and an ‘upper portion’ of the fabrication-completed structure described with reference to FIGS. 6A to 6C.

Referring to FIGS. 5, 10A, and 10B, a cell array substrate 100 may be provided. The cell array substrate 100 may include a first cell array substrate 110, a second cell array substrate 120, and a third cell array substrate 130, which are sequentially stacked.

In an embodiment, the first cell array substrate 110 may be a silicon substrate, a silicon germanium substrate, a germanium substrate, or a single crystalline epitaxial layer grown on a single-crystalline silicon substrate. The second cell array substrate 120 may be formed of or include a material having an etch selectivity with respect to the first cell array substrate 110. In an embodiment, the second cell array substrate 120 may be formed of or include silicon oxide. The third cell array substrate 130 may be formed of or include a semiconductor material (e.g., polysilicon).

A first mold structure ML1 may be formed on the cell array substrate 100. The formation of the first mold structure ML1 may include alternately stacking the first interlayer insulating layers ILD1 and the first sacrificial layers SL1. The first sacrificial layers SL1 of the first mold structure ML1 may be formed of a material which can be etched with a high etch selectivity with respect to the first interlayer insulating layers ILD1. In an embodiment, the first sacrificial layers SL1 may be formed of an insulating material different from the first interlayer insulating layers ILD1. For example, the first sacrificial layers SL1 may be formed of or include silicon nitride, and the first interlayer insulating layers ILD1 may be formed of or include silicon oxide.

Next, the first outer holes OH1 and the first channel holes CHI may be formed to extend into the first interlayer insulating layers ILD1 and the first sacrificial layers SL1 in the first direction D1. The first outer holes OH1 and the first channel holes CHI may be formed through an anisotropic etching process, which is performed on the first mold structure ML1. In an embodiment, the structures, such as the separation trench STR and the penetration hole TH, may be formed together through the etching process, but the present disclosure is not limited to this example.

As a result of the etching process, the extension holes EH may be formed to be extended from the first outer holes OH1 and the first channel holes CH1 into the cell array substrate 100. Due to a process variation in the etching process, the extension holes EH in the cell array substrate 100 may be formed to have the same depth or different depths from each other.

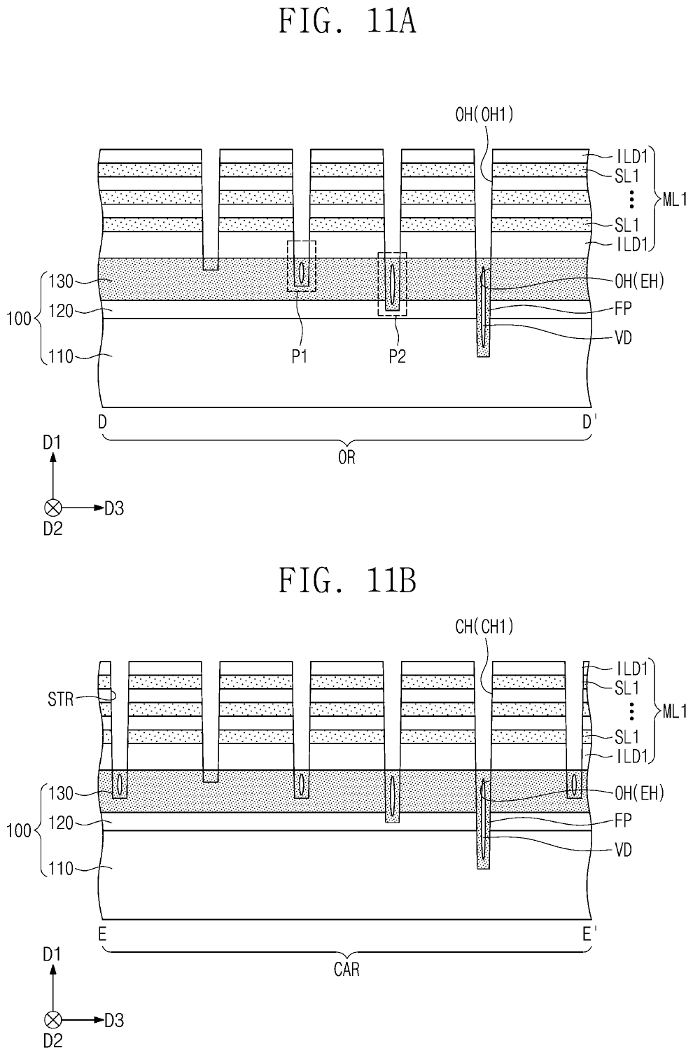

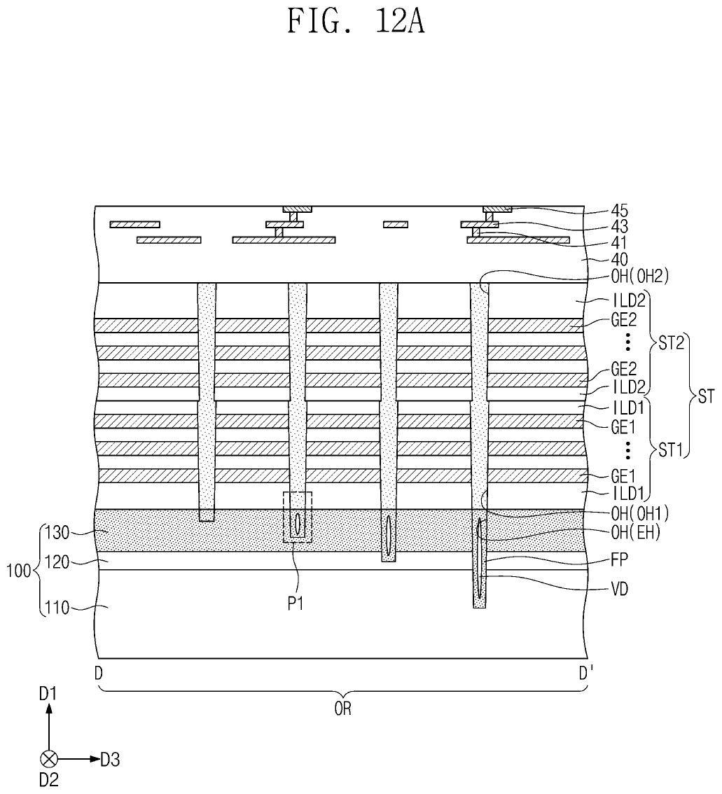

Referring to FIGS. 5, 11A, and 11B, the filling patterns FP may be formed in the extension holes EH, respectively. The filling pattern FP may be at least partially in the extension hole EH. The filling pattern FP may be formed by a SEG process using the cell array substrate 100 as a seed layer. As an example, the filling pattern FP may be grown using the third cell array substrate 130 as the seed layer, but it may not be grown using the second cell array substrate 120 as the seed layer. In the case where the structures, such as the separation trench STR and the penetration hole TH, are formed before the SEG process, the filling pattern FP may be formed in such structures, but the present disclosure is not limited to this example. The filling pattern FP may be enclosed or at least partially surrounded by the cell array substrate 100.

Since the filling pattern FP is formed from an inner surface of the extension hole EH through the SEG process, a portion of the extension hole EH may not include the filling pattern FP therein to form the void VD closed or defined by the filling pattern FP. As an example, the void VD may not be formed in some of the filling patterns FP. As another example, the void VD may be formed in each of the filling patterns FP.

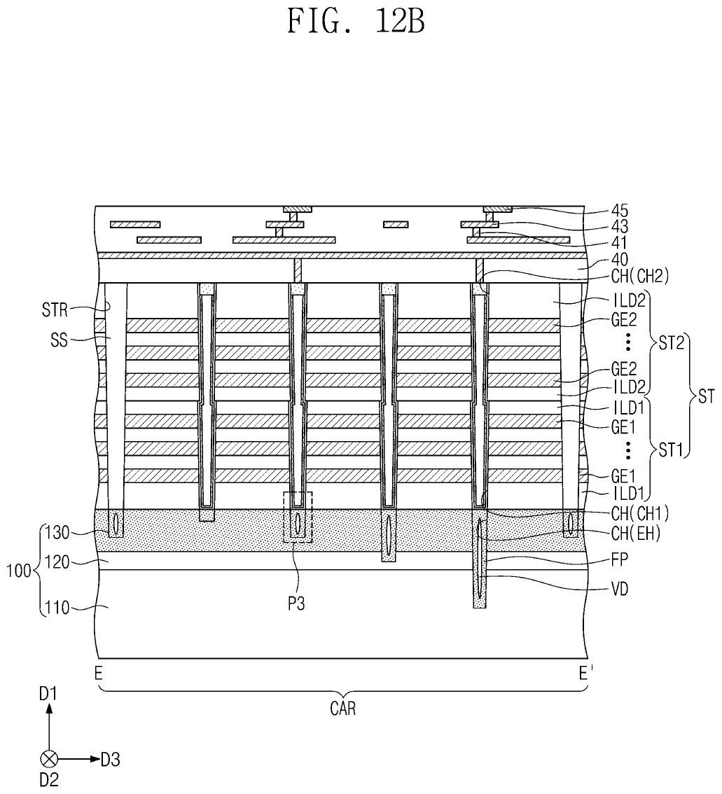

Referring to FIGS. 5, 12A, and 12B, a second mold structure (not shown) may be formed on the first mold structure ML1. The second mold structure may include alternately stacking the second interlayer insulating layers ILD2 and the second sacrificial layers (not shown). The second interlayer insulating layers ILD2 and the second sacrificial layers may have the same or similar features as the first interlayer insulating layers ILD1 and the first sacrificial layers SL1. Thereafter, the second outer holes OH2 and the second channel holes CH2 may be formed to extend into the second mold structure in the first direction D1. The second outer holes OH2 and the second channel holes CH2 may be vertically overlapped with the first outer holes OH1 and the first channel holes CH1, respectively. Although not shown, a patterning process may be performed to form a stepwise structure in the first mold structure ML1 and the second mold structure on the cell array extension region EXR, and the third insulating layer 50 may be formed to cover or overlap the first mold structure ML1 and the second mold structure.

Next, the outer vertical structure OVS and the cell vertical structure CVS may be formed in the outer hole OH and the channel hole CH. The formation of the cell vertical structure CVS may include sequentially forming the data storage pattern DSP, the vertical semiconductor pattern VSP, and the gapfill insulating pattern VI in the channel hole CH. The data storage pattern DSP may cover or overlap the filling pattern FP in the channel hole CH and may be interposed between the filling pattern FP and the vertical semiconductor pattern VSP. Thereafter, the channel pad CHP may be formed in an upper portion of the channel hole CH. The outer vertical structure OVS may be formed together with the cell vertical structure CVS or may be formed by a process that is different from that for the cell vertical structure CVS.

An isotropic etching process, in which the separation trench STR is used as a supply path of an etchant material, may be performed to remove the first sacrificial layers SL1 and the second sacrificial layers. Thereafter, the first and second gate electrodes GE1 and GE2, which constitute the stack ST, may be formed in empty spaces, which are formed by removing the first sacrificial layers SL1 and the second sacrificial layers. As an example, the first sacrificial layers SL1 and the second sacrificial layers may not be removed from some regions. In the case where the outer hole OH is formed in such regions, the outer vertical structure OVS in the final stage may extend into the sacrificial layers.

The separation pattern SS may be formed to fill the separation trench STR. Thereafter, the second insulating layer 40, the connection contact plugs 41, the connection circuit interconnection lines 43, and the second bonding pads 45 may be formed on the stack ST. The connection contact plugs 41, the connection circuit interconnection lines 43, and the second bonding pads 45 may be electrically connected to each other, and the second insulating layer 40 may be formed to enclose these components.

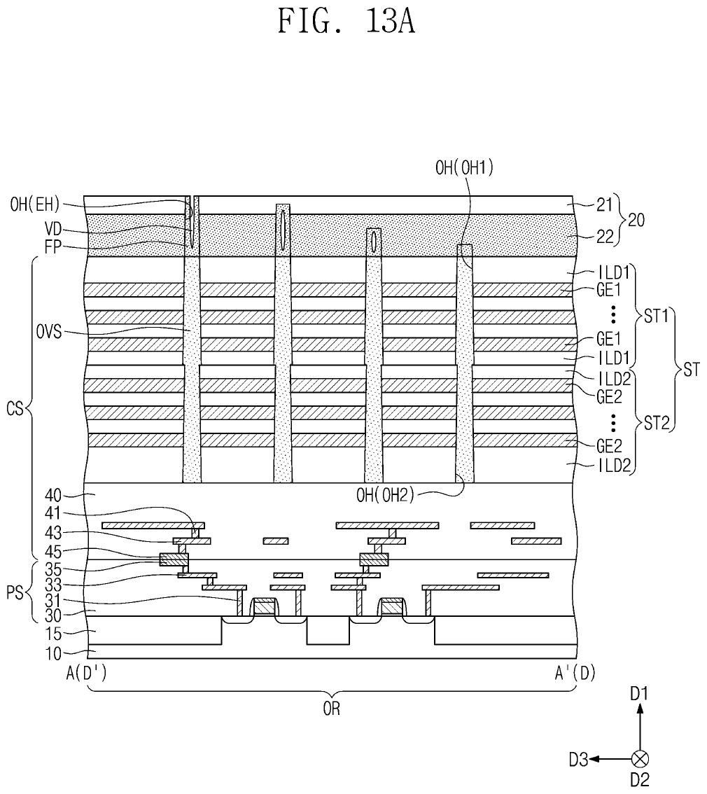

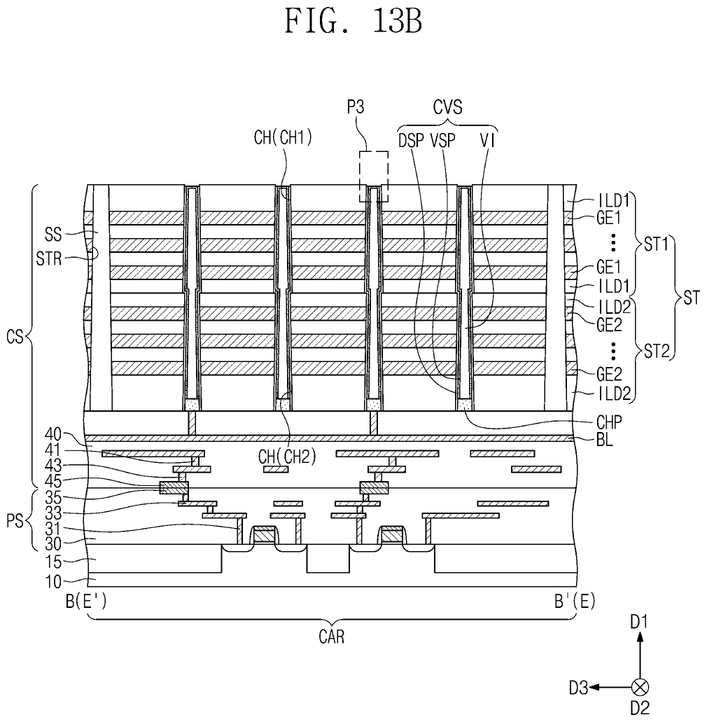

Referring to FIGS. 5, 13A, and 13B, the peripheral circuit structure PS and the cell array structure CS may be combined with each other. In detail, the first bonding pads 35 of the peripheral circuit structure PS may be bonded to the second bonding pads 45 of the cell array structure CS to be in contact with each other. Thus, the first insulating layer 30 and the second insulating layer 40 may be bonded to each other.

Since the first bonding pads 35 and the second bonding pads 45 are bonded to each other, it may be possible to invert the cell array structure CS. Accordingly, in the following description on steps of the fabrication process after the bonding process, the terms of ‘top surface’, ‘bottom surface’, ‘upper portion’, and ‘lower portion’ may mean the terms ‘top surface’, ‘bottom surface’, ‘upper portion’, and ‘lower portion’ described with reference to FIGS. 6A to 6C.

After the bonding process, the first cell array substrate 110 may be removed. The removal of the first cell array substrate 110 may include at least one of a grinding process, a planarization process, a dry etching process, and a wet etching process. In an embodiment, a portion of the filling pattern FP, which is enclosed by the first cell array substrate 110, may also be removed during the removal of the first cell array substrate 110. Accordingly, the void VD may be exposed to the outside, but the present disclosure is not limited to this example. After the removal of the first cell array substrate 110, a top surface of the filling pattern FP may be located at a level that is equal to or lower than a top surface of the second cell array substrate 120. The top surface of the second cell array substrate 120 may be exposed to the outside.

On the cell array region CAR, the second and third cell array substrates 120 and 130 may be removed. Here, the filling pattern FP on the cell array region CAR may be removed, and the data storage pattern DSP of the cell vertical structure CVS and the uppermost one of the first interlayer insulating layers ILD1 may be exposed to the outside. Thereafter, the exposed portion of the data storage pattern DSP may be removed. Thus, the vertical semiconductor pattern VSP in the channel hole CH may be exposed to the outside.

Although the second and third cell array substrates 120 and 130 on the cell array region CAR are removed, the second and third cell array substrates 120 and 130 on the outer region OR may not be removed. The unremoved portions of the second and third cell array substrates 120 and 130 may be the upper and lower base patterns 21 and 22, respectively, which constitute the base pattern 20.

Referring back to FIGS. 5 to 6C, the source structure CST may be formed on the cell array structure CS. The formation of the source structure CST may include sequentially depositing the first source layer CST1 and the second source layer CST2. The source structure CST may be formed on the entire exposed surface of the cell array structure CS, and then, a portion of the source structure CST may be removed by a patterning process. A portion of the source structure CST may remain to cover or overlap the uppermost one of the first interlayer insulating layers ILD1 and the cell vertical structure CVS. Another portion of the source structure CST may be formed to cover or overlap the base pattern 20. In an embodiment, although not shown, another portion of the source structure CST may be left on the outer region OR.

Next, the protection layer 80 may be formed on the entire exposed surface of the cell array structure CS. In an embodiment, the protection layer 80 may be a composite layer, which is formed by applying a deposition process and/or a coating process at least two times. In the case where the void VD is exposed to the outside near the top surface of the base pattern 20, the void VD may be covered with the protection layer 80. Accordingly, the uppermost end VDa of the void VD may be defined by the protection layer 80.

According to an embodiment of the present disclosure, due to a process variation in the etching process, the outer holes OH and the channel holes CH may be formed to have various depths. Here, the holes formed in the cell array substrate 100 may be provided with the filling pattern FP, and in this case, the cell vertical structures CVS may be formed to have end portions that are located at levels similar to each other. Accordingly, it may be possible to reduce the difficulty in a process of fabricating a three-dimensional semiconductor memory device. In addition, it may be possible to reduce a process failure, which may be caused by a metal diffusion phenomenon, unlike the case where an etch stop layer formed of a metallic material is used to reduce the process variation.

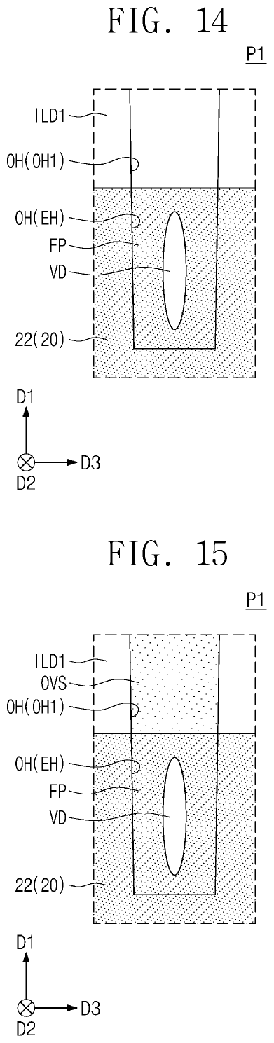

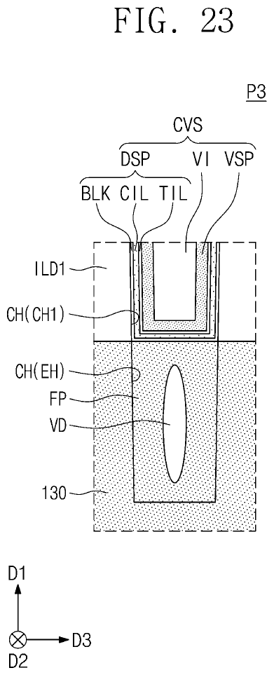

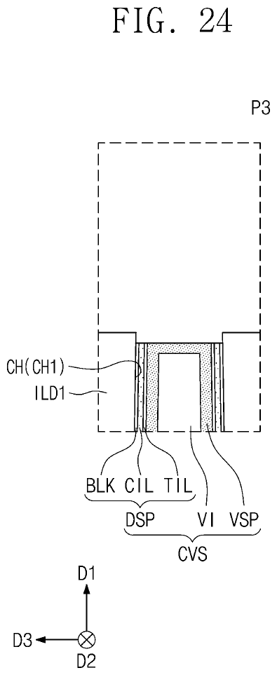

FIGS. 14, 16, and 18 are enlarged views corresponding to a portion P1 of FIG. 11A. FIGS. 15, 17, and 19 are enlarged views corresponding to a portion P1 of FIG. 12A. FIGS. 20 to 22 are enlarged views corresponding to a portion P2 of FIG. 11A. FIGS. 23, 25, and 27 are enlarged views corresponding to a portion P3 of FIG. 12B. FIGS. 24, 26, and 28 are enlarged views corresponding to a portion P3 of FIG. 13B.

Hereinafter, fabrication methods for the embodiments of FIGS. 7A to 8C will be described in more detail with reference to FIGS. 14 to 28. For concise description, a previously described element may be identified by the same reference number without repeating a corresponding description thereof.

Referring to FIGS. 14 and 15, the three-dimensional semiconductor memory device of FIG. 7A may be formed. In detail, as shown in FIG. 14, the filling pattern FP may be formed to have a flat top surface. As shown in FIG. 14, the top surface of the filling pattern FP may be formed at the same level as the top surface of the third cell array substrate 130, but the present disclosure is not limited to this example. Thereafter, the outer vertical structure OVS may be formed, as shown in FIG. 15. Since the filling pattern FP is formed to have the flat top surface, the outer vertical structure OVS may be formed to have a flat bottom surface.

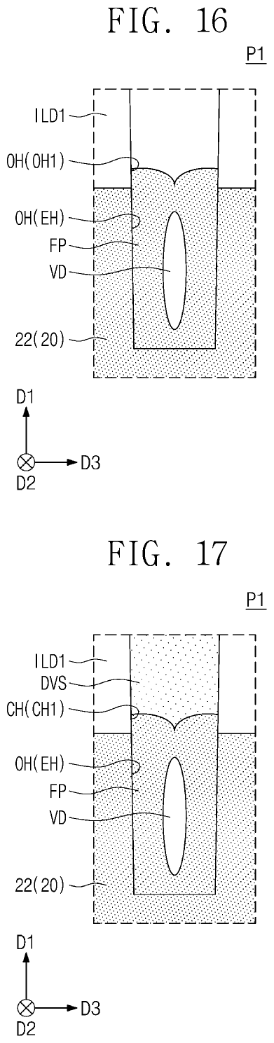

Referring to FIGS. 16 and 17, the three-dimensional semiconductor memory device of FIG. 7B may be formed. In detail, as shown in FIG. 16, the filling pattern FP may be formed to have an uneven shape. The lowermost end of the top surface of the filling pattern FP may be formed at a level higher than the top surface of the third cell array substrate 130. Next, the outer vertical structure OVS may be formed, as shown in FIG. 17. Due to the position of the top surface of the filling pattern FP, the lowermost end of the outer vertical structure OVS may be formed at a level higher than the top surface of the third cell array substrate 130. In the case where the peripheral circuit structure PS and the cell array structure CS are bonded to each other in the final step, the uppermost end of the bottom surface of the filling pattern FP and the uppermost end of the outer vertical structure OVS may be formed at a level lower than a bottom surface of the lower base pattern 22, as shown in FIG. 7B.

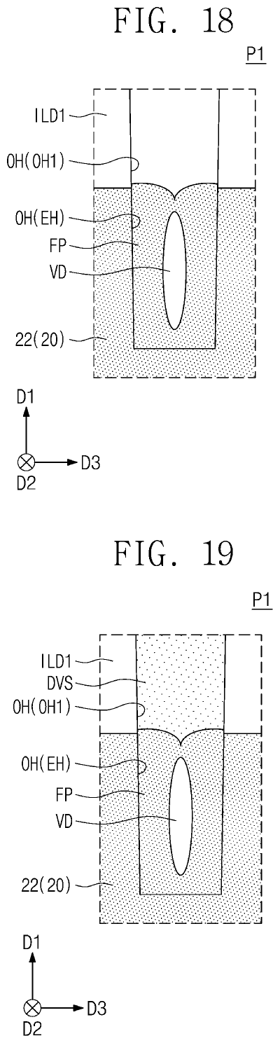

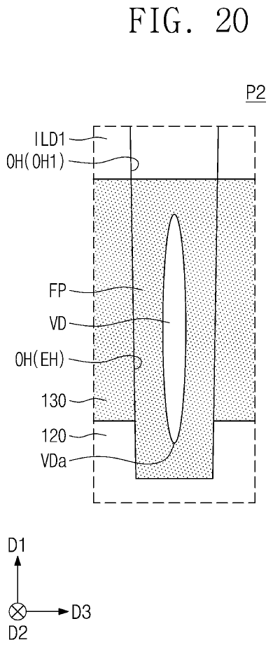

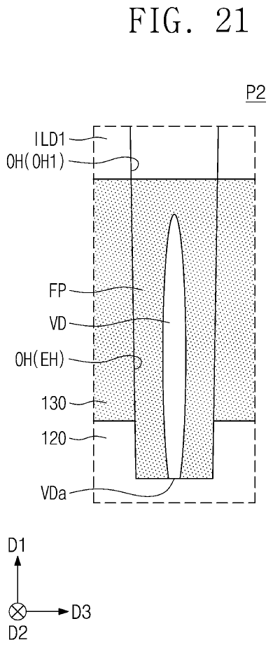

Referring to FIGS. 18 and 19, the three-dimensional semiconductor memory device of FIG. 7C may be formed. In detail, as shown in FIG. 18, the filling pattern FP may be formed to have an uneven shape. The lowermost end of the top surface of the filling pattern FP may be formed at a level lower than the top surface of the third cell array substrate 130. Thereafter, the outer vertical structure OVS may be formed, as shown in FIG. 19. Due to the position of the top surface of the filling pattern FP, the lowermost end of the outer vertical structure OVS may be formed at a level lower than the top surface of the third cell array substrate 130. In the case where the peripheral circuit structure PS and the cell array structure CS are bonded to each other in the final step, the uppermost end of the bottom surface of the filling pattern FP and the uppermost end of the outer vertical structure OVS may be formed at a level higher than the bottom surface of the lower base pattern 22, as shown in FIG. 7C.

Referring to FIG. 20, the three-dimensional semiconductor memory device of FIG. 7D may be formed. The lowermost end of the void VD may be formed at a level lower than a bottom surface of the third cell array substrate 130. The lowermost end of the void VD may be defined by the filling pattern FP. In the case where the peripheral circuit structure PS and the cell array structure CS are bonded to each other in the final step, the uppermost end VDa of the void VD may be formed at a level higher than the top surface of the lower base pattern 22, as shown in FIG. 7D.

Referring to FIG. 21, the three-dimensional semiconductor memory device of FIG. 7E may be formed. The lowermost end of the void VD may be formed at a level lower than the bottom surface of the third cell array substrate 130. In the case where the filling pattern FP is grown through the SEG process using the third cell array substrate 130 as the seed layer but not the second cell array substrate 120, the filling pattern FP may not cover or overlap the entirety of the second cell array substrate 120. Accordingly, the lowermost end of the void VD may be defined by and exposed to the second cell array substrate 120. In the case where the peripheral circuit structure PS and the cell array structure CS are bonded to each other in the final step, the uppermost end VDa of the void VD may be formed at a level higher than the top surface of the lower base pattern 22, as shown in FIG. 7D, and may be defined by the lower base pattern 22.

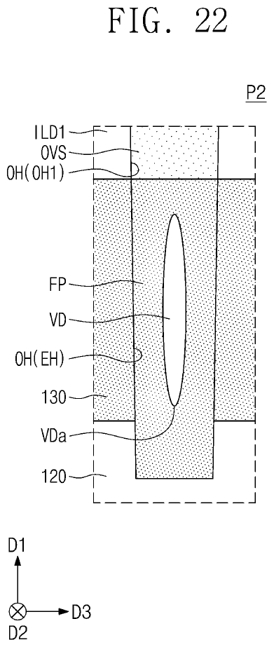

Referring to FIG. 22, the three-dimensional semiconductor memory device of FIG. 7F may be formed. The lowermost end of the void VD may be formed at a level higher than the bottom surface of the third cell array substrate 130. The lowermost end of the void VD may be defined by the filling pattern FP. In the case where the peripheral circuit structure PS and the cell array structure CS are bonded to each other in the final step, the uppermost end VDa of the void VD may be formed at a level lower than the top surface of the lower base pattern 22, as shown in FIG. 7F.

Referring to FIGS. 23 and 24, the three-dimensional semiconductor memory device of FIG. 8A may be formed. In detail, as shown in FIG. 23, the filling pattern FP may be formed to have a flat top surface. Thus, the bottom surface of the cell vertical structure CVS may be formed to have a flat shape. The top surface of the filling pattern FP and the bottom surface of the cell vertical structure CVS may be formed at the same level as the top surface of the third cell array substrate 130 as shown in FIG. 23, but the present disclosure is not limited to this example. Next, the peripheral circuit structure PS and the cell array structure CS may be bonded to each other, as shown in FIG. 24. The cell array substrate 100 on the cell vertical structure CVS may be removed, and the data storage pattern DSP may be partially removed to expose the vertical semiconductor pattern VSP. As a result of the partial removal of the data storage pattern DSP, the top surface of the cell vertical structure CVS (i.e., the top surface of the vertical semiconductor pattern VSP) may be recessed from the uppermost one of the first interlayer insulating layers ILD1. Thereafter, as shown in FIG. 8A, the source structure CST may be formed to include the protruding portion CSTp in the recess region.

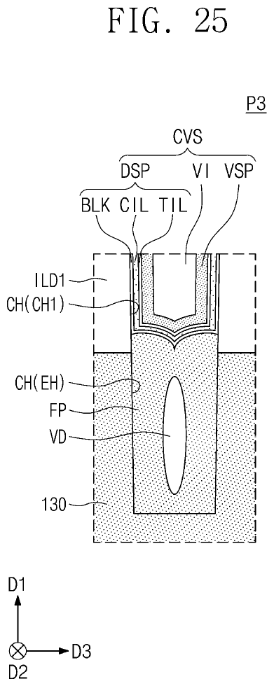

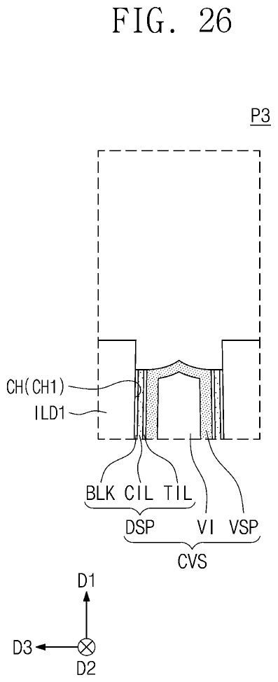

Referring to FIGS. 25 and 26, the three-dimensional semiconductor memory device of FIG. 8B may be formed. In detail, as shown in FIG. 25, the filling pattern FP may be formed to have an uneven shape. Accordingly, the bottom surface of the cell vertical structure CVS may be formed to have an uneven shape. Here, the lowermost end of the vertical semiconductor pattern VSP may be formed at a level higher than the top surface of the third cell array substrate 130. Next, the peripheral circuit structure PS and the cell array structure CS may be bonded to each other, as shown in FIG. 26. The cell array substrate 100 on the cell vertical structure CVS may be removed, and the data storage pattern DSP may be partially removed to expose the vertical semiconductor pattern VSP. As a result of the partial removal of the data storage pattern DSP of the vertical semiconductor pattern VSP, at least a portion of the top surface of the cell vertical structure CVS (i.e., the top surface of the vertical semiconductor pattern VSP) may be recessed from the uppermost one of the first interlayer insulating layers ILD1. Thereafter, as shown in FIG. 8B, the source structure CST may be formed to include the protruding portion CSTp in the recess region.

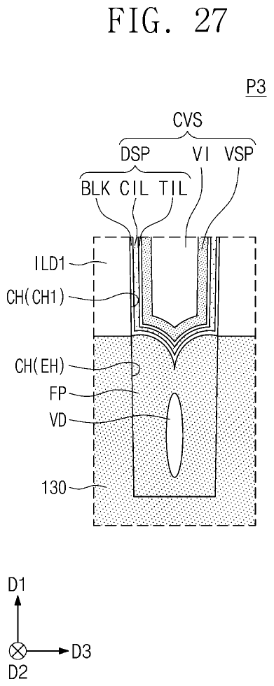

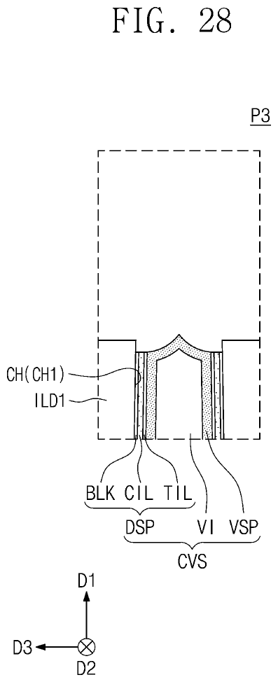

Referring to FIGS. 27 and 28, the three-dimensional semiconductor memory device of FIG. 8C may be formed. In detail, as shown in FIG. 27, the filling pattern FP may be formed to have an uneven shape. Accordingly, the bottom surface of the cell vertical structure CVS may be formed to have an uneven shape. Here, the lowermost end of the vertical semiconductor pattern VSP may be formed at a level lower than the top surface of the third cell array substrate 130. Next, the peripheral circuit structure PS and the cell array structure CS may be bonded to each other, as shown in FIG. 28. The cell array substrate 100 on the cell vertical structure CVS may be removed, and the data storage pattern DSP may be partially removed to expose the vertical semiconductor pattern VSP. As a result of the partial removal of the data storage pattern DSP of the vertical semiconductor pattern VSP, at least a portion of the top surface of the cell vertical structure CVS (i.e., the top surface of the vertical semiconductor pattern VSP) may be recessed from the uppermost one of the first interlayer insulating layers ILD1. Thereafter, as shown in FIG. 8C, the source structure CST may be formed to include the protruding portion CSTp in the recess region.

According to an embodiment of the present disclosure, a filling pattern may be provided in an end portion of a channel hole, and thus, end portions of cell vertical structures may be formed at similar levels, regardless of a process variation. Accordingly, it may be possible to reduce a process difficulty in a process of fabricating a three-dimensional semiconductor memory device. Furthermore, an etch stop layer, which is formed of a metallic material, is not required to reduce the process variation, and thus, it may be possible to reduce a process failure, which is caused by the etch stop layer.

While example embodiments of the present disclosure have been particularly shown and described, it will be understood by one of ordinary skill in the art that variations in form and detail may be made therein without departing from the spirit and scope of the attached claims.

What is claimed is:

1. A three-dimensional semiconductor memory device, comprising:
a peripheral circuit structure on a peripheral substrate;
a cell array structure on the peripheral circuit structure, the cell array structure comprising a cell array region and an outer region;
a source structure on the cell array region;
a base pattern on the outer region;
a cell vertical structure that extends into the cell array structure in the cell array region and is electrically connected to the source structure;
an outer vertical structure that extends into the cell array structure in the outer region; and
a filling pattern that extends from the outer vertical structure into the base pattern;
wherein the filling pattern defines a void,
wherein an uppermost end of the cell vertical structure is located at a lower level than a top surface of the source structure.

2. The three-dimensional semiconductor memory device of claim 1, wherein:
the filling pattern comprises a first filling pattern and a second filling pattern that are spaced apart from each other,
the void comprises a first void defined by the first filling pattern and a second void defined by the second filling pattern, and
an uppermost end of the first void and an uppermost end of the second void are located at different levels from each other.

3. The three-dimensional semiconductor memory device of claim 1, wherein:
the filling pattern comprises a third filling pattern and a fourth filling pattern that are spaced apart from each other, and
the third filling pattern defines the void.

4. The three-dimensional semiconductor memory device of claim 1, wherein:
the base pattern comprises an upper base pattern on the cell array structure and a lower base pattern between the cell array structure and the upper base pattern, and
an uppermost end of the void is located at a higher level than or equal to a top surface of the lower base pattern.

5. The three-dimensional semiconductor memory device of claim 1, wherein:
the base pattern comprises an upper base pattern on the cell array structure and a lower base pattern between the cell array structure and the upper base pattern, and
an uppermost end of the void is located at a lower level than a top surface of the lower base pattern.

6. The three-dimensional semiconductor memory device of claim 1, wherein an uppermost end of the void is defined by the filling pattern.

7. The three-dimensional semiconductor memory device of claim 1, further comprising a protection layer on the base pattern, wherein an uppermost end of the void is defined by the base pattern or the protection layer.

8. The three-dimensional semiconductor memory device of claim 1, wherein:
an uppermost end of the outer vertical structure is located at a higher level than or equal to a bottom surface of the base pattern.

9. The three-dimensional semiconductor memory device of claim 1, wherein:
an uppermost end of the outer vertical structure is located at a lower level than a bottom surface of the base pattern.

10. The three-dimensional semiconductor memory device of claim 1, wherein a top surface of the outer vertical structure has an uneven or a flat shape.

11. The three-dimensional semiconductor memory device of claim 1, wherein the cell array structure comprises:
a stack including a plurality of gate electrodes on the peripheral substrate; and
an insulating layer on the stack,
wherein the outer vertical structure extends into at least one of the stack and the insulating layer.

12. The three-dimensional semiconductor memory device of claim 1, wherein the source structure comprises a protruding portion that is on the cell vertical structure and extends into the cell array structure.

13. A three-dimensional semiconductor memory device, comprising:
a peripheral circuit structure on a peripheral substrate;
a cell array structure on the peripheral circuit structure, the cell array structure comprising a cell array region and an outer region;
a source structure on the cell array region;
a base pattern on the outer region;
a cell vertical structure that extends into the cell array structure in the cell array region and is electrically connected to the source structure;
an outer vertical structure that extends into the cell array structure in the outer region; and
a filling pattern that extends from the outer vertical structure and into the base pattern,
wherein the source structure comprises a protruding portion that is on the cell vertical structure and extends into the cell array structure.

14. The three-dimensional semiconductor memory device of claim 13, wherein a top surface of the cell vertical structure has an uneven or a flat shape.

15. The three-dimensional semiconductor memory device of claim 13, wherein:
an uppermost end of the cell vertical structure is located at a lower level than a top surface of the source structure.

16. The three-dimensional semiconductor memory device of claim 13, wherein:
the cell array structure comprises a stack comprising a plurality of gate electrodes and a plurality of interlayer insulating layers that are alternately stacked on the peripheral substrate, and
the protruding portion of the source structure extends into the stack.

17. The three-dimensional semiconductor memory device of claim 16, wherein:
a lowermost end of the source structure is located at a lower level than a top surface of an uppermost one of the interlayer insulating layers.

18. The three-dimensional semiconductor memory device of claim 13, wherein the filling pattern defines a void.

19. An electronic system, comprising:
a three-dimensional semiconductor memory device; and
a controller that is electrically connected to the three-dimensional semiconductor memory device through an input/output pad, wherein the controller is configured to control the three-dimensional semiconductor memory device,
wherein the three-dimensional semiconductor memory device comprises:
a peripheral circuit structure on a peripheral substrate;
a cell array structure on the peripheral circuit structure, the cell array structure comprising a cell array region and an outer region;
a source structure on the cell array region;
a base pattern on the outer region;
a cell vertical structure that extends into the cell array structure in the cell array region and is electrically connected to the source structure;
an outer vertical structure that extends into the cell array structure in the outer region; and
a filling pattern that extends from the outer vertical structure and into the base pattern,
wherein the filling pattern defines a void, and
wherein an uppermost end of the cell vertical structure is located at a lower level than a top surface of the source structure.

20. The electronic system of claim 19, wherein the source structure comprises a protruding portion that is on the cell vertical structure and extends into the cell array structure.
